(19) United States
(12) Patent Application Publication
(10) Pub. No.: US 2024/0209166 A1
(43) Pub. Date: Jun. 27, 2024

(54) RESIN COMPOSITION FOR NON-CONDUCTIVE FILM WITH EXCELLENT HIGH TEMPERATURE PROPERTIES FOR 3D TSV PACKAGES

(71) Applicant: Henkel AG & Co. KGaA, Duesseldorf (DE)

(72) Inventors: Jie Bai, Aliso Viejo, CA (US); Qizhuo Zhuo, Irvine, CA (US); James Sungwook Jang, Seoul (KR); Kyu Chang Shim, Irvine, CA (US)

(21) Appl. No.: 18/416,190

(22) Filed: Jan. 18, 2024

Related U.S. Application Data
(63) Continuation of application No. PCT/US2022/037829, filed on Jul. 21, 2022.
(60) Provisional application No. 63/224,366, filed on Jul. 21, 2021.

(51) Int. Cl. C08J 5/18; C08J 3/24; C08K 5/3445; H01L 23/29

(52) U.S. Cl. CPC C08J 5/18; C08J 3/24; C08K 5/3445; H01L 23/295; C08J 2363/10

(57) ABSTRACT

The disclosure relates to compositions for forming films and the use of said films in three-dimension through-silicon-via (3D TSV) packages. In certain aspects, the disclosure relates to compositions comprising one or more resins, one or more imidazoles with latent thermal activity, one or more inorganic fillers, and one or more additives, to B-stage films prepared from the disclosed compositions, and to cured films obtained after cure of the disclosed compositions.

### FIELD OF THE DISCLOSURE

Aspects of the disclosure relate to compositions for forming films and the use of said films in three-dimension through-silicon-via (3D TSV) packages. In certain aspects, the disclosure relates to compositions comprising one or more resins, one or more imidazoles with latent thermal activity, one or more inorganic fillers, and one or more additives, to B-stage films prepared from the disclosed compositions, and to cured films obtained after cure of the disclosed compositions. In certain aspects, cured films obtained after cure of the disclosed compositions have particular physical properties and/or combinations of physical properties. In certain aspects, the disclosure relates to underfill films prepared from disclosed compositions, such as wafer-level underfill films (WAUFs). Embodiments of the disclosed films are suitable for, for example, use in thermal compression bonding processes.

### BACKGROUND

As it looks to the next generation of high performance 3D TSV packages, the materials industry faces the need to improve the high temperature properties of film materials (e.g., underfill film materials). The realization of this goal may bring such benefits as higher thermal stability and, consequently, higher reliability in applications across the automotive, computing, networking, and telecommunication industries. Features that may be associated with improved high temperature properties of film materials include a comparatively high Tg (glass transition temperature), a comparatively low CTE (coefficient of thermal expansion), and a comparatively high modulus at, e.g., 250° C.

Problems have been encountered in using films prepared from certain conventional resin compositions comprising maleimide-containing resins in thermal compression bonding processes. For example, in some instances, B-stage films prepared from certain conventional resin compositions comprising maleimide-containing resins may have a DSC onset temperature that is less than 100° C. to 150° C. When such B-stage films are used in thermal compression bonding processes where the bondhead contact temperature becomes from 100° C. to 150° C. (e.g., as occurs in a process where a bondhead contact temperature is from 130° C. to 210° C.), material entrapment issues can arise at solder joints. In other instances, B-stage films prepared from conventional resin compositions comprising maleimide-containing resins may have a DSC onset temperature that is greater than the melting temperature of solder (e.g., lead-free solder), such as a DSC onset temperature that is greater than, for example, 217° C. When such B-stage films are used in thermal compression bonding processes, in some instances, solder extrusion issues may arise. In some instances, solder extrusion issues may also arise where a B-stage film prepared from a conventional resin composition comprising one or more maleimide-containing resins has a ΔT from the DSC onset temperature to the DSC peak temperature that is, for example, greater than 20° C., such as about 40° C.

### SUMMARY

In view of at least the considerations discussed above, there is an interest in compositions comprising one or more resins, one or more inorganic fillers, and one or more additives, to B-stage films prepared from said compositions, and to cured films obtained after cure of said compositions, wherein said compositions comprise one or more imidazoles with latent thermal activity. As used herein, an imidazole with latent thermal activity refers to an imidazole that, when combined in the amount of 0.20 g with 1.0 g of NC-3000-L epoxy resin (Nippon Kayaku), yields a composition that, when measured on a TA Instruments Thermal Analyzer DSC Q20 in N₂, from room temperature to 300° C. and at a 10° C./min ramping rate, exhibits a DSC onset temperature of at least 145° C. and a DSC peak temperature of at least 150° C. For example, in some embodiments, an imidazole with latent thermal activity, when analyzed as just described, exhibits a DSC onset temperature of at least 145° C., at least 150° C., at least 155° C., at least 160° C., at least 165° C., at least 170° C., at least 175° C., or at least 180° C. For example, in some embodiments, an imidazole with latent thermal activity, when analyzed as just described, exhibits a DSC onset temperature of from 145° C. to 180° C., such as from 145° C. to 175° C., 145° C. to 170° C., 145° C. to 160° C., 150° C. to 180° C., 150° C. to 175° C., 150° C. to 170° C., 150° C. to 160° C., 155° C. to 175° C., 155° C. to 170° C., or from 155° C. to 165° C. In some embodiments, an imidazole with latent thermal activity, when analyzed as just described, exhibits a DSC peak temperature of at least 150° C., at least 155° C., at least 160° C., at least 165° C., at least 170° C., at least 175° C., or at least 185° C. For example, in some embodiments, an imidazole with latent thermal activity, when analyzed as just described, exhibits a DSC peak temperature of from 150° C. to 185° C., such as from 150° C. to 180° C., 150° C. to 175° C., 150° C. to 170° C., 150° C. to 165° C., 150° C. to 160° C., 160° C. to 180° C., 165° C. to 175° C., or 160° C. to 170° C.

For the avoidance of doubt, it is to be understood that the DSC onset temperature and/or DSC peak temperature exhibited by a composition prepared and measured as just described (i.e., a composition comprising 0.20 g of an imidazole with latent thermal activity and 1.0 g of NC-3000-L epoxy resin (Nippon Kayaku)) may be the same as or different from the DSC onset temperature and/or DSC peak temperature exhibited by a composition comprising the same imidazole with latent thermal activity but with other components, such as one or more resins, or more inorganic fillers, and/or one or more additives.

In some embodiments, an imidazole with latent thermal activity comprises at least two electron-withdrawing groups.

By comparison, imidazoles that do not constitute imidazoles with latent thermal activity include those that, when combined in the amount of 0.20 g with 1.0 g of NC-3000-L epoxy resin (Nippon Kayaku), yield a composition that, when measured on a TA Instruments Thermal Analyzer DSC Q20 in N₂, from room temperature to 300° C. and at a 10° C./min ramping rate, exhibits a DSC onset temperature of less than 145° C. and a DSC peak temperature of less than 150° C.

As a non-limiting illustration, four imidazoles were analyzed as described above. Specifically, four separate experiments were performed. In each experiment, 0.20 g of one of Imidazole A, Imidazole B, Imidazole C, and Imidazole D was combined with 1.0 g of NC-3000-L epoxy resin (Nippon Kayaku), and the resulting composition was measured on a TA Instruments Thermal Analyzer DSC Q20 in N₂, from room temperature to 300° C. and at a 10° C./min ramping rate. The DSC onset temperature and DSC peak temperature was measured. The results are tabulated below. Imidazole A is 4-methyl-2-phenyl-1H-imidazole-5-methanol. Imidazole B is 2-phenyl-4,5-dihydroxymethylimidazole. Imidazole C is 2-phenylimidazole. Imidazole D is 2-ethyl-4-methyl-1H-imidazole-1-propanenitrile.

| | Imidazole | Imidazole | Imidazole | Imidazole |
|---|---|---|---|---|
| | A | B | C | D |
| DSC Onset | 175.10 | 164.68 | 103.52 | 135.30 |
| Temperature | | | | |
| (° C.)¹ | | | | |
| DSC Peak | 179.00 | 168.46 | 119.97 (1^{st} Peak), | 143.80 |
| Temperature | | | 127.26 (2^{nd} Peak) | |
| (° C.)¹ | | | | |

¹Test conditions: 0.20 g of each imidazole was combined with 1.0 g of NC-3000-L epoxy resin (Nippon Kayaku) and each of the resulting compositions was analyzed using a TA Instruments Thermal Analyzer DSC Q20 in N₂, from room temperature to 300° C. and at a 10° C./min ramping rate.

Imidazole A and Imidazole B are exemplary imidazoles with latent thermal activity, whereas Imidazole C and Imidazole D are not considered imidazoles with latent thermal activity within the context of this disclosure. As shown above, when analyzed as described above, the compositions comprising Imidazole A or Imidazole B each exhibited a DSC onset temperature at least 145° C. and a DSC peak temperature of at least 150° C., whereas the compositions comprising Imidazole C or Imidazole D each exhibited a DSC onset temperature of less than 145° C. and a DSC peak temperature of less than 150° C.

Embodiments of the disclosed compositions address issues discussed above. For example, embodiments of underfill films prepared from disclosed compositions are suitable for thermal compression bonding processes, such as thermal compression bonding processes for 3D TSV stacking applications. Additionally, embodiments of underfill films prepared from disclosed compositions exhibit one or more of good die corner coverage, gap filling, and electrical interconnect joint formation.

In some embodiments, aspects of the present disclosure are directed to:
1. A composition comprising:
   one or more resins selected from the group consisting of maleimide-containing resins, nadimide-containing resins, itaconimide-containing resins, epoxy resins, (meth)acrylate-containing resins, and phenolic-containing resins,
   one or more imidazoles with latent thermal activity,
   one or more inorganic fillers, and
   one or more additives selected from the group consisting of adhesion promoters and film formers, wherein:
      after the composition forms a film, the film has the following physical properties:
         a Tg of >200° C. as measured by dynamic mechanical analysis (DMA),
         a storage modulus at 25° C. of <6.5 GPa,
         a storage modulus at 250° C.>0.1 GPa, and
         a coefficient of thermal expansion (CTE)<250 ppm/° C.
2. The composition of embodiment 1, wherein the imidazole with latent activity is an imidazole comprising at least two electron withdrawing groups.
3. The composition of any of the previous embodiments, wherein the imidazole comprises at least two electron-withdrawing groups independently selected from hydroxymethyl and phenyl.
4. The composition of any of the previous embodiments, wherein the imidazole is represented by

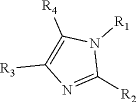

wherein:
R₁ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl,
R₂ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl,
R₃ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl, and
R₄ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl, provided that the imidazole comprises at least two electron withdrawing groups.
5. The composition of any of the previous embodiments, wherein the maleimide-containing resin is a compound represented by

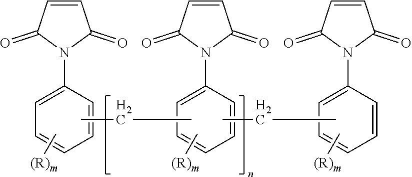

wherein:
each R is independently selected from the group consisting of H and substituted or unsubstituted alkyl;
each m is independently selected from the group consisting of 0, 1, 2, 3, or 4; and
n is 0, 1, 2, 3, 4, or 5, or is a compound represented by

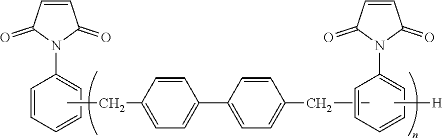

wherein n is 0, 1, 2, 3, 4, or 5.
6. The composition of any of the previous embodiments, wherein the (meth)acrylate resin is represented by

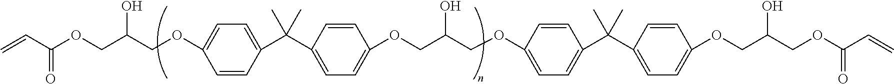

wherein n is 0, 1, 2, 3, 4, or 5.
7. The composition of any of the previous embodiments, wherein the epoxy resin is a compound represented by

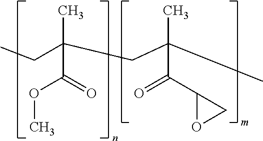

wherein n is 0, 1, 2, 3, 4, or 5, and m is 0, 1, 2, 3, 4, or 5.
8. The composition of any of the previous embodiments, wherein, after the composition forms a film, the film has the following physical properties:
   a differential scanning calorimetry (DSC) onset temperature from 130° C. to 250° C. as measured by DSC with a 10° C./min ramping rate, and
   a minimum film melt viscosity from 10 Pa·s to 10,000 Pa·s as measured using a DHR2 rheometer with a 10° C./min ramping rate in N₂.
9. The composition of any of the previous embodiments, wherein after the composition forms a film, the film has a ΔT from the DSC onset temperature to the DSC peak temperature that is less than 20° C. or less than 15° C.
10. A method of preparing a cured film, the method comprising providing a composition according to any one of the previous embodiments; casting the composition into a film; and exposing the cast film to elevated temperature to cure the film.
11. A method of preparing a cured film, the method comprising
providing a composition comprising
   one or more resins selected from the group consisting of maleimide-containing resins, nadimide-containing resins, itaconimide-containing resins, epoxy resins, (meth)acrylate-containing resins, and phenolic-containing resins,
   one or more imidazoles with latent thermal activity,
   one or more inorganic fillers, and
   one or more additives selected from the group consisting of adhesion promoters and film formers;
casting the composition into a film; and
exposing the cast film to elevated temperature to cure the film.
12. The method according to embodiment 11, wherein the one or more imidazoles with latent thermal activity is one or more imidazoles comprising at least two electron withdrawing groups.
13. A cured film prepared according to the method of embodiment 11 or embodiment 12.
14. A film prepared according to the method of any one of embodiments 11-13, wherein the film has the following physical properties:
   a Tg of >200° C. as measured by dynamic mechanical analysis (DMA),
   a storage modulus at 25° C. of <6.5 GPa,
   a storage modulus at 250° C.>0.1 GPa, and
   a coefficient of thermal expansion (CTE)<250 ppm/° C.
15. The film of embodiment 13 or embodiment 14, wherein the film is an underfill film.

### BRIEF DESCRIPTION OF THE DRAWINGS

FIG. 1 presents DSC (differential scanning calorimetry) data for an exemplary composition of the disclosure (Inventive Example 3).

FIG. 2 presents melt viscosity data for an exemplary composition of the disclosure (Inventive Example 3).

FIG. 3 presents DMA (dynamic mechanical analysis) data for an exemplary composition of the disclosure (Inventive Example 3).

FIG. 4 presents TMA (thermomechanical analysis) data for an exemplary composition of the disclosure (Inventive Example 3).

FIG. 5 presents DSC (differential scanning calorimetry) data for an exemplary composition of the disclosure (Inventive Example 8).

FIG. 6 presents melt viscosity data for an exemplary composition of the disclosure (Inventive Example 8).

FIG. 7 presents DMA (dynamic mechanical analysis) data for an exemplary composition of the disclosure (Inventive Example 8).

FIG. 8 presents TMA (thermomechanical analysis) data for an exemplary composition of the disclosure (Inventive Example 8).

### DETAILED DESCRIPTION

The disclosed compositions and processes may be understood more readily by reference to the following detailed description taken in connection with the accompanying figures, which form a part of this disclosure.

In accordance with the disclosure, there are provided compositions comprising one or more resins, one or more imidazoles with latent thermal activity, one or more inorganic fillers, and one or more additives. In some embodiments, the one or more resins are selected from the group consisting of maleimide-containing resins, nadimide-containing resins, itaconimide-containing resins, epoxy resins, (meth)acrylate-containing resins, and phenolic-containing resins. In some embodiments, the one or more additives selected from the group consisting of adhesion promoters and film formers. In some embodiments, the one or more imidazoles with latent thermal activity are one or more imidazoles comprising at least two electron withdrawing groups.

In some embodiments, after the composition forms a film, the film has certain features and/or properties that make the film suitable for use in thermal compression bonding processes. For example, in some embodiments, after the composition forms a film, the film has a Tg of >100° C. as measured by dynamic mechanical analysis (DMA), a storage modulus at 25° C. of <4 GPa, a storage modulus at 250° C.>0.1 GPa, and a coefficient of thermal expansion (CTE)<250 ppm/° C. In some embodiments, after the composition forms a B-stage film, the B-stage film has a differential scanning calorimetry (DSC) onset temperature from 130° C. to 250° C. as measured by DSC with a 10° C./min ramping rate and a minimum film melt viscosity from 10 Pa·s to 10,000 Pa·s as measured using a DHR2 rheometer with a 10° C./min ramping rate in N₂.

In some embodiments, after the composition forms a cured film, the cured film has a Tg of >100° C., >125° C., >150° C., >160° C., >165° C., >170° C.>175° C., >180° C., >185° C., >190° C., >200° C., >210° C., >220° C., >230° C., >240° C., >250° C., >260° C., >270° C., >280° C., >290° C., or >300° C., each as measured by dynamic mechanical analysis (DMA). In some embodiments, after the composition forms a cured film, the cured film has a Tg of from 100° C. to 110° C., from 110° C. to 120° C., from 120° C. to 130° C., from 130° C. to 140° C., from 140° C. to 150° C., from 150° C. to 160° C., from 160° C. to 170° C., from 170° C. to 180° C., from 180° C. to 190° C., from 190° C. to 200° C., from 200° C. to 210° C., from 210° C. to 220° C., from 220° C. to 230° C., from 230° C. to 240° C., from 240° C. to 250° C., from 250° C. to 260° C., from 260° C. to 270° C., from 270° C. to 280° C., from 280° C. to 290° C., or from 290° C. to 300° C., each as measured by DMA.

In some embodiments, after the composition forms a cured film, the cured film has a Tg of >100° C., >125° C., >150° C., >160° C., >165° C., >170° C., >175° C., >180° C., >185° C., >190° C., >200° C., >210° C., >220° C., >230° C., >240° C., or >250° C., each as measured by thermomechanical analysis (TMA). In some embodiments, after the composition forms a cured film, the cured film has a Tg of from 100° C. to 110° C., from 110° C. to 120° C., from 120° C. to 130° C., from 130° C. to 140° C., from 140° C. to 150° C., from 150° C. to 160° C., from 160° C. to 170° C., from 170° C. to 180° C., from 180° C. to 190° C., from 190° C. to 200° C., from 200° C. to 210° C., from 210° C. to 220° C., from 220° C. to 230° C., from 230° C. to 240° C., or from 240° C. to 250° C., each as measured by TMA. In some embodiments, after the composition forms a cured film, the cured film has a Tg of from 140° C. to 200° C., such as from 150° C. to 190° C., from 160° C. to 190° C., or from 160° C. to 180° C.

In some embodiments, after the composition forms a B-stage film, the B-stage film has a storage modulus at 25° C. of <3 GPa, <3.5 GPa, <4 GPa, <4.5 GPa, <5 GPa, <5.5 GPa, <6 GPa, or <6.5 GPa.

In some embodiments, after the composition forms a B-stage film, the B-stage film has a storage modulus at 25° C. of from 2.0 GPa to 3.0 GPa, from 3.0 GPa to 3.5 GPa, from 3.5 GPa to 4.0 GPa, from 4.0 GPa to 4.5 GPa, from 4.5 GPa to 5.0 GPa, from 5.0 GPa to 5.5 GPa, from 5.5 GPa to 6.0 GPa, or from 6.0 GPa to 6.5 GPa. In some embodiments, after the composition forms a B-stage film, the B-stage film has a storage modulus at 25° C. of from 3.0 GPa to 6.5 GPa. In some embodiments, after the composition forms a B-stage film, the B-stage film has a storage modulus at 25° C. of from 3.5 GPa to 6.0 GPa. In some embodiments, after the composition forms a B-stage film, the B-stage film has a storage modulus at 25° C. of from 4.0 GPa to 5.5 GPa.

In some embodiments, after the composition forms a B-stage film, the B-stage film has a storage modulus at 250° C. of >0.1 GPa, >0.2 GPa, >0.3 GPa, >0.4 GPa, >0.5 GPa, >0.6 GPa, >0.7 GPa, >0.8 GPa, >0.9 GPa, >1.0 GPa, or >1.1 GPa. In some embodiments, after the composition forms a B-stage film, the B-stage film has a storage modulus at 250° C. of from 0.1 GPa to 0.2 GPa, 0.2 GPa to 0.3 GPa, from 0.3 GPa to 0.4 GPa, from 0.4 GPa to 0.5 GPa, from 0.5 GPa to 0.6 GPa, from 0.6 GPa to 0.7 GPa, from 0.7 GPa to 0.8 GPa, from 0.8 GPa to 0.9 GPa, from 0.9 GPa to 1.0 GPa, or from 1.0 GPa to 1.1 GPa. In some embodiments, after the composition forms a B-stage film, the B-stage film has a storage modulus at 250° C. of from 0.4 GPa to 1.2 GPa. In some embodiments, after the composition forms a B-stage film, the B-stage film has a storage modulus at 250° C. of from 0.5 GPa to 1.2 GPa.

In some embodiments, after the composition forms a B-stage film, the B-stage film has a storage modulus at 230° C. of >0.1 GPa, >0.2 GPa, >0.3 GPa, or >0.4 GPa, >0.5 GPa, >0.6 GPa, >0.7 GPa, >0.8 GPa, >0.9 GPa, >1.0 GPa, >1.1 GPa, or >1.2 GPa. In some embodiments, after the composition forms a B-stage film, the B-stage film has a storage modulus at 230° C. of from 0.1 GPa to 0.2 GPa, 0.2 GPa to 0.3 GPa, from 0.3 GPa to 0.4 GPa, from 0.4 GPa to 0.5 GPa, from 0.5 GPa to 0.6 GPa, from 0.6 GPa to 0.7 GPa, from 0.7 GPa to 0.8 GPa, from 0.8 GPa to 0.9 GPa, from 0.9 GPa to 1.0 GPa, from 1.0 GPa to 1.1 GPa, or from 1.1 GPa to 1.2 GPa. In some embodiments, after the composition forms a B-stage film, the B-stage film has a storage modulus at 230° C. of from 0.5 GPa to 1.2 GPa. In some embodiments, after the composition forms a B-stage film, the B-stage film has a storage modulus at 230° C. of from 0.6 GPa to 1.2 GPa.

In some embodiments, after the composition forms a cured film, the cured film has a coefficient of thermal expansion (CTE)<60 ppm/ºC, <70 ppm/ºC, <80 ppm/° C., <90 ppm/ºC, <100 ppm/ºC, <110 ppm/ºC, <120 ppm/ºC, <130 ppm/ºC, <140 ppm/° C., <150 ppm/ºC, <160 ppm/ºC, <170 ppm/ºC, <180 ppm/° C., <190 ppm/° C., <200 ppm/° C., <210 ppm/ºC, <220 ppm/ºC, <230 ppm/° C., <240 ppm/ºC, or <250 ppm/ºC.

In some embodiments, after the composition forms a cured film, the cured film has a coefficient of thermal expansion (CTE) above Tg<100 ppm/° C., <110 ppm/ºC, <120 ppm/° C., <130 ppm/° C., <140 ppm/ºC, <150 ppm/° C., <160 ppm/° C., <170 ppm/ºC, <180 ppm/ºC, <190 ppm/ºC, <200 ppm/ºC, <210 ppm/ºC, <220 ppm/ºC, <230 ppm/ºC, <240 ppm/° C., or <250 ppm/° C. In some embodiments, after the composition forms a cured film, the cured film has a coefficient of thermal expansion (CTE) above Tg from 50 ppm/° C. to 80 ppm/° C. In some embodiments, after the composition forms a cured film, the cured film has a coefficient of thermal expansion (CTE) above Tg from 60 ppm/° C. to 80 ppm/° C. In some embodiments, after the composition forms a cured film, the cured film has a coefficient of thermal expansion (CTE) above Tg from 60 ppm/° C. to 70 ppm/° C.

In some embodiments, after the composition forms a B-stage film, the B-stage film has a minimum film melt viscosity from 500 Pa·s to 8,000 Pa·s as measured using a DHR2 rheometer with a 10° C./min ramping rate in N₂. In some embodiments, after the composition forms a B-stage film, the B-stage film has a minimum film melt viscosity from 900 Pa·s to 6,500 Pa·s as measured using a DHR2 rheometer with a 10° C./min ramping rate in N₂. In some embodiments, after the composition forms a B-stage film, the B-stage film has a minimum film melt viscosity from 2,000 Pa·s to 6,000 Pa's as measured using a DHR2 rheometer with a 10° C./min ramping rate in N₂. In some embodiments, after the composition forms a B-stage film, the B-stage film has a minimum film melt viscosity from 2,000 Pa·s to 4,000 Pa's as measured using a DHR2 rheometer with a 10° C./min ramping rate in N₂. In some embodiments, after the composition forms a B-stage film, the B-stage film has a minimum film melt viscosity from 4,000 Pa·s to 6,000 Pa·s as measured using a DHR2 rheometer with a 10° C./min ramping rate in N₂.

In some embodiments, after the composition forms a B-stage film, the B-stage film has a minimum film melt viscosity from 500 Pa·s to 600 Pa·s, from 600 Pa·s to 700 Pa·s, from 700 Pa·s to 800 Pa·s, from 800 Pa·s to 900 Pa·s, from 900 Pa·s to 1,000 Pa·s, from 1,000 Pa·s to 1,100 Pa·s, from 1,100 Pa·s to 1,200 Pa·s, from 1,200 Pas to 1,300 Pa·s, from 1,300 Pa·s to 1,400 Pa·s, from 1,400 Pa·s to 1,500 Pa·s, from 1,500 Pa·s to 1,600 Pa·s, from 1,600 Pa·s to 1,700 Pa·s, from 1,700 Pa·s to 1,800 Pa·s, from 1,800 Pa·s to 1,900 Pa·s, from 1,900 Pa·s to 2,000 Pa·s, from 2,000 Pa·s to 2,100 Pas, from 2,100 Pa·s to 2,200 Pa·s, from 2,200 Pa·s to 2,300 Pa·s, from 2,300 Pa·s to 2,400 Pa·s, from 2,400 Pa·s to 2,500 Pa·s, from 2,500 Pa·s to 2,600 Pa·s, from 2,600 Pas to 2,700 Pa·s, from 2,700 Pa·s to 2,800 Pa·s, from 2,800 Pa·s to 2,900 Pa·s, from 2,900 Pa·s to 3,000 Pa·s, from 3,000 Pa·s to 3,100 Pa·s, from 3,100 Pa·s to 3,200 Pa·s, from 3,200 Pa·s to 3,300 Pa·s, from 3,300 Pa·s to 3,400 Pa·s, from 3,400 Pa·s to 3,500 Pas, from 3,500 Pa·s to 3,600 Pa·s, from 3,600 Pa·s to 3,700 Pa·s, from 3,700 Pa·s to 3,800 Pa·s, from 3,800 Pa·s to 3,900 Pa·s, from 3,900 Pa·s to 4,000 Pa·s, from 4,000 Pas to 4,100 Pa·s, from 4,100 Pa·s to 4,200 Pa·s, from 4,200 Pa·s to 4,300 Pa·s, from 4,300 Pa·s to 4,400 Pa·s, from 4,400 Pa·s to 4,500 Pa·s, from 4,500 Pa·s to 4,600 Pa·s, from 4,600 Pa·s to 4,700 Pa·s, from 4,700 Pa·s to 4,800 Pa·s, from 4,800 Pa·s to 4,900 Pa·s, from 4,900 Pa·s to 5,000 Pa·s, from 5,000 Pa·s to 5,100 Pa·s, from 5,100 Pa·s to 5,200 Pa·s, from 5,200 Pa·s to 5,300 Pa·s, from 5,300 Pa·s to 5,400 Pa·s, from 5,400 Pa·s to 5,500 Pa·s, from 5,500 Pa·s to 5,600 Pa·s, from 5,600 Pa·s to 5,700 Pa·s, from 5,700 Pa·s to 5,800 Pa·s, from 5,800 Pa·s to 5,900 Pa·s, from 5,900 Pa·s to 6,000 Pa·s, from 6,000 Pa·s to 6,100 Pa·s, from 6,100 Pa·s to 6,200 Pa·s, from 6,200 Pa·s to 6,300 Pas, from 6,300 Pa·s to 6,400 Pa·s, from 6,400 Pa·s to 6,500 Pa·s, from 6,500 Pa·s to 6,600 Pa·s, from 6,600 Pa·s to 6,700 Pa·s, from 6,700 Pa·s to 6,800 Pa·s, from 6,800 Pa·s to 6,900 Pa·s, from 6,900 Pa·s to 7,000 Pa·s, from 7,000 Pa·s to 7,100 Pa·s, from 7,100 Pa·s to 7,200 Pa·s, from 7,200 Pa·s to 7,300 Pa·s, from 7,300 Pa·s to 7,400 Pa·s, from 7,400 Pa·s to 7,500 Pa·s, from 7,500 Pa·s to 7,600 Pa·s, from 7,600 Pa·s to 7,700 Pa·s, from 7,700 Pa·s to 7,800 Pa·s, from 7,800 Pa·s to 7,900 Pa·s, from 7,900 Pa·s to 8,000 Pa·s, from 8,000 Pa·s to 8,100 Pa·s, from 8,100 Pa·s to 8,200 Pa·s, from 8,200 Pa·s to 8,300 Pa·s, from 8,300 Pa·s to 8,400 Pa·s, from 8,400 Pa·s to 8,500 Pa·s, from 8,500 Pa·s to 8,600 Pa·s, from 8,600 Pa·s to 8,700 Pa·s, from 8,700 Pa·s to 8,800 Pa·s, from 8,800 Pa·s to 8,900 Pa·s, from 8,900 Pa·s to 9,000 Pa·s, from 9,000 Pa·s to 9,100 Pa·s, from 9,100 Pa·s to 9,200 Pa·s, from 9,200 Pa·s to 9,300 Pa·s, from 9,300 Pa's to 9,400 Pa·s, from 9,400 Pa·s to 9,500 Pa·s, from 9,500 Pa·s to 9,600 Pa·s, from 9,600 Pa·s to 9,700 Pa·s, from 9,700 Pa·s to 9,800 Pa·s, from 9,800 Pa·s to 9,900 Pa·s, or from 9,900 Pa·s to 10,000 Pa·s, as measured using a DHR2 rheometer with a 10° C./min ramping rate in N₂.

In some embodiments, after the composition forms a B-stage film, the B-stage film has a minimum film melt viscosity from 400 Pa·s to 7,000 Pa·s as measured using a DHR2 rheometer with a 10° C./min ramping rate in N₂. In some embodiments, after the composition forms a B-stage film, the B-stage film has a minimum film melt viscosity from 500 Pa·s to 8,000 Pa·s as measured using a DHR2 rheometer with a 10° C./min ramping rate in N₂.

In some embodiments, after the composition forms a B-stage film, the B-stage film has a differential scanning calorimetry (DSC) onset temperature of from 130° C. to 140° C., from 140° C. to 150° C., from 150° C. to 160° C., from 160° C. to 170° C., from 170° C. to 180° C., from 180° C. to 190° C., from 190° C. to 200° C., from 200° C. to 210° C., from 210° C. to 220° C., from 220° C. to 230° C., from 230° C. to 240° C., or from 240° C. to 250° C., as measured by DSC with a 10° C./min ramping rate in N₂.

In some embodiments, after the composition forms a B-stage film, the B-stage film has a differential scanning calorimetry (DSC) onset temperature of from about 130° C. to about 140° C., from about 140° C. to about 150° C., from about 150° C. to about 160° C., from about 160° C. to about 170° C., from about 170° C. to about 180° C., from about 180° C. to about 190° C., from about 190° C. to about 200° C., from about 200° C. to about 210° C., from about 210° C. to about 220° C., from about 220° C. to about 230° C., from about 230° C. to about 240° C., or from about 240° C. to about 250° C., as measured by DSC with a 10° C./min ramping rate in N₂.

In some embodiments, after the composition forms a B-stage film, the B-stage film has a DSC onset temperature from 150° C. to 190° C. as measured by DSC with a 10° C./min ramping rate in N₂. In some embodiments, after the composition forms a B-stage film, the B-stage film has a DSC onset temperature from 140° C. to 180° C. as measured by DSC with a 10° C./min ramping rate in N₂. In some embodiments, after the composition forms a B-stage film, the B-stage film has a DSC onset temperature from 150° C. to 180° C. as measured by DSC with a 10° C./min ramping rate in N₂. In some embodiments, after the composition forms a B-stage film, the B-stage film has a DSC onset temperature from 140 to 160° C. as measured by DSC with a 10° C./min ramping rate in N₂. In some embodiments, after the composition forms a B-stage film, the B-stage film has a DSC onset temperature from 140 to 150° C. as measured by DSC with a 10° C./min ramping rate in N₂. In some embodiments, after the composition forms a B-stage film, the B-stage film has a DSC onset temperature from 170 to 180° C. as measured by DSC with a 10° C./min ramping rate in N₂.

In some embodiments, after the composition forms a B-stage film, the B-stage film has a ΔT from the DSC onset temperature to the DSC peak temperature that is less than 20° C., less than 15° C., less than 10° C., or less than 5° C. In some embodiments, after the composition forms a B-stage film, the B-stage film has a ΔT from the DSC onset temperature to the DSC peak temperature that is from 0° C. to 5° C., from 5° C. to 10° C., from 10° C. to 15° C., or from 15° C. to 20° C. In some embodiments, after the composition forms a B-stage film, the B-stage film has a ΔT from the DSC onset temperature to the DSC peak temperature that is 0° C., 1° C., 2° C., 3° C., 4° C., 5° C., 6° C., 7° C., 8° C., 9° C., 10° C., 11° C., 12° C., 13° C., 14° C., 15° C., 16° C., 17° C., 18° C., 19° C., or 20° C. Without wishing to be bound by theory, it is believed that a ΔT from the DSC onset temperature to the DSC peak temperature that is less than 20° C., less than 15° C., less than 10° C., or less than 5° C., or that is from 0° C. to 5° C., from 5° C. to 10° C., from 10° C. to 15° C., or from 15° C. to 20° C. represents fast curing kinetics that, for example, prevent solder extrusion (a phenomenon that, in at least some embodiments, makes a composition less suitable or unsuitable for thermal compression bonding) from occurring. Conversely, without wishing to be bound by theory, it is believed that a B-stage film having a ΔT from the DSC onset temperature to the DSC peak temperature that is greater than or equal to 20° C. is not suitable for thermal compression bonding processes. For instance, certain B-stage films prepared from compositions that comprise a bis-maleimide resin, an epoxy resin, and 4,4-diaminodiphenyl sulfone but that do not comprise one or more imidazoles with latent thermal activity (e.g., one or more imidazoles comprising at least two electron withdrawing groups, such as imidazoles comprising at least two electron withdrawing groups as disclosed herein) are known to exhibit a ΔT from the DSC onset temperature to the DSC peak temperature that is greater than or equal to than 20° C. and, without wishing to be bound by theory, are believed to be unsuitable for thermal compression bonding processes.

The present disclosure refers to certain organic groups as being, in some embodiments, “substituted.” The term “substituted” means that the subject organic group bears one or more substituents, where a substituent is an atom or a group of atoms that replaces a hydrogen atom on the subject organic group. Where an organic group is substituted, a substituent may replace one or more hydrogen atoms, ranging from replacement of exactly one hydrogen atom to the replacement of all hydrogen atoms on the subject organic group. Where an organic group may bear multiple substituents, the substituents are selected independently and can be, but need not be, identical.

The present disclosure refers to certain organic groups as being, in some embodiments, “unsubstituted.” The term “unsubstituted” means that the subject organic group bears no substituents (as that term is described above).

Compositions of the disclosure, as noted above, include, among other constituents, one or more imidazoles comprising at least two electron withdrawing groups. In some embodiments, the imidazole comprising at least two electron withdrawing groups is a substituted imidazole comprising a substituent on the 2-position and optionally a substituent on the 4-position, a substituent on the 5-position, and/or a substituent on the nitrogen at the 1-position. In some embodiments, the imidazole comprising at least two electron withdrawing groups is a substituted imidazole comprising an electron-withdrawing substituent (alternatively referred to herein as an electron-withdrawing group) on the 2-position and optionally a substituent on the 4-position, a substituent on the 5-position, and/or a substituent on the nitrogen at the 1-position.

Exemplary electron withdrawing groups include, but are not limited to, substituted or unsubstituted aryl groups (e.g., phenyl), cyano (—CN), halide (—X) (e.g., fluoro (—F), bromo (—Br), and iodo (—I)), —CHO, —COOH, and amino (—NR₁R₂, wherein each of R₁ and R₂ is independently selected from a hydrogen atom or a substituted or unsubstituted alkyl group), alkyl groups substituted with one or more groups independently selected from cyano (—CN), halide (—X) (e.g., fluoro (—F), bromo (—Br), and iodo (—I)), —CHO, —COOH, and amino (—NR₁R₂, wherein each of R₁ and R₂ is independently selected from a hydrogen atom or a substituted or unsubstituted alkyl group), and oxygen-containing groups (e.g., alkyl groups substituted with one or more hydroxy groups). Without wishing to be bound by theory, it is believed that electron withdrawing groups reduce electron density on the imidazole ring (e.g., at the tertiary nitrogen of the imidazole) and/or attenuate the reactivity of the imidazole (e.g., attenuate the reactivity of the tertiary nitrogen of the imidazole).

In some embodiments, the imidazole is represented by Formula (I)

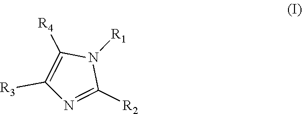

wherein:
R₁ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl,
R₂ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl,
R₃ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl, and
R₄ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl, provided that the imidazole comprises at least two electron withdrawing groups.

In some embodiments, the imidazole comprises at least two electron-withdrawing groups independently selected from the group consisting of substituted or unsubstituted aryl groups (e.g., phenyl), cyano (—CN), halide (—X) (e.g., fluoro (—F), bromo (—Br), and iodo (—I)), —CHO, —COOH, amino (—NR₁R₂, wherein each of R₁ and R₂ is independently selected from a hydrogen atom or a substituted or unsubstituted alkyl group), alkyl groups substituted with one or more groups independently selected from cyano (—CN), halide (—X) (e.g., fluoro (—F), bromo (—Br), and iodo (—I)), —CHO, —COOH, and amino (—NR₁R₂, wherein each of R₁ and R₂ is independently selected from a hydrogen atom or a substituted or unsubstituted alkyl group), and oxygen-containing groups.

In some embodiments, the imidazole comprises at least two electron-withdrawing groups independently selected from the group consisting of hydroxymethyl and phenyl.

In some embodiments, the imidazole comprises at least two electron-withdrawing groups independently selected from organic groups that reduce electron density on the imidazole ring and/or attenuate the reactivity of the imidazole.

In some embodiments, the imidazole comprising at least two electron withdrawing groups is represented by Formula (I) wherein R₁ is selected from the group consisting of H, substituted or unsubstituted C₁-C₆ alkyl, and substituted or unsubstituted C₆-C₁₀ aryl.

In some embodiments, the imidazole comprising at least two electron withdrawing groups is represented by Formula (I) wherein R₁ is selected from the group consisting of H, substituted or unsubstituted C₁-C₆ alkyl, substituted C₆ aryl, and phenyl.

In some embodiments, the imidazole comprising at least two electron withdrawing groups is represented by Formula (I) wherein R₁ is selected from the group consisting of H and substituted or unsubstituted C₁-C₆ alkyl.

In some embodiments, the imidazole comprising at least two electron withdrawing groups is represented by Formula (I) wherein R₁ is selected from the group consisting of H and unsubstituted C₁-C₆ alkyl.

In some embodiments, the imidazole comprising at least two electron withdrawing groups is represented by Formula (I) wherein R₁ is H.

In some embodiments, the imidazole comprising at least two electron withdrawing groups is represented by Formula (I) wherein R₂ is selected from the group consisting of H, substituted or unsubstituted C₁-C₆ alkyl, and substituted or unsubstituted C₆-C₁₀ aryl.

In some embodiments, the imidazole comprising at least two electron withdrawing groups is represented by Formula (I) wherein R₂ is selected from the group consisting of H, substituted or unsubstituted C₁-C₆ alkyl, substituted C₆ aryl, and phenyl.

In some embodiments, the imidazole comprising at least two electron withdrawing groups is represented by Formula (I) wherein R₂ is selected from the group consisting of substituted or unsubstituted C₁-C₆ alkyl, substituted C₆ aryl, and phenyl.

In some embodiments, the imidazole comprising at least two electron withdrawing groups is represented by Formula (I) wherein R₂ is selected from the group consisting of unsubstituted C₁-C₆ alkyl and phenyl.

In some embodiments, the imidazole comprising at least two electron withdrawing groups is represented by Formula (I) wherein R₂ is phenyl.

In some embodiments, the imidazole comprising at least two electron withdrawing groups is represented by Formula (I) wherein R₃ and R₄ are each independently selected from the group consisting of H, substituted or unsubstituted C₁-C₆ alkyl, and substituted or unsubstituted C₆-C₁₀ aryl.

In some embodiments, the imidazole comprising at least two electron withdrawing groups is represented by Formula (I) wherein R₃ and R₄ are each independently selected from the group consisting of H, substituted or unsubstituted C₁-C₆ alkyl, substituted C₆ aryl, and phenyl.

In some embodiments, the imidazole comprising at least two electron withdrawing groups is represented by Formula (I) wherein R₃ and R₄ are each independently selected from the group consisting of substituted or unsubstituted C₁-C₆ alkyl, substituted C₆ aryl, and phenyl.

In some embodiments, the imidazole comprising at least two electron withdrawing groups is represented by Formula (I) wherein R₃ and R₄ are each independently selected from the group consisting of substituted or unsubstituted C₁-C₆ alkyl.

In some embodiments, the imidazole comprising at least two electron withdrawing groups is represented by Formula (I) wherein R₃ and R₄ are each independently selected from the group consisting of substituted C₁-C₆ alkyl.

In some embodiments, the imidazole comprising at least two electron withdrawing groups is represented by Formula (I) wherein R₃ and R₄ are each independently selected from the group consisting of substituted C₁-C₆ alkyl, wherein each independently selected substituted C₁-C₆ alkyl is substituted with one or more substituents selected from the group consisting of halogen, hydroxy, cyano, C₁-C₆ alkoxy, carboxylic acid, ester (e.g., —C(O)OR₅, wherein R₅ is a substituted or unsubstituted alkyl group), ketone (e.g., —C(O)R₆, wherein R₆ is a substituted or unsubstituted alkyl group), amido (e.g., —C(O)N(R₇)(R₈), wherein each of R₇ and R₈ is independently selected from the group consisting of H, substituted alkyl, and unsubstituted alkyl), amino (e.g., —N(R₉)(R₁₀), wherein each of R₉ and R₁₀ is independently selected from the group consisting of H, substituted alkyl, and unsubstituted alkyl), and thioalkyl (e.g., —S—R₁₁, wherein R₁₁ is a substituted or unsubstituted alkyl group).

In some embodiments, the imidazole comprising at least two electron withdrawing groups is represented by Formula (I) wherein R₃ and R₄ are each independently selected from the group consisting of substituted C₁-C₆ alkyl, wherein each independently selected substituted C₁-C₆ alkyl is substituted with one or more substituents selected from the group consisting of halogen, hydroxy, cyano, C₁-C₆ alkoxy, and carboxylic acid.

In some embodiments, the imidazole comprising at least two electron withdrawing groups is represented by Formula (I) wherein R₃ and R₄ are each independently selected from the group consisting of substituted C₁-C₆ alkyl, wherein each independently selected substituted C₁-C₆ alkyl is substituted with one or more substituents selected from the group consisting of halogen, hydroxy, and C₁-C₆ alkoxy.

In some embodiments, the imidazole comprising at least two electron withdrawing groups is represented by Formula (I) wherein R₃ and R₄ are each independently selected from the group consisting of substituted C₁-C₆ alkyl, wherein each independently selected substituted C₁-C₆ alkyl is substituted with one or more hydroxy groups.

In some embodiments, the imidazole comprising at least two electron withdrawing groups is represented by Formula (I) wherein R₃ and R₄ are each independently selected from the group consisting of substituted C₁-C₆ alkyl, wherein each independently selected substituted C₁-C₆ alkyl is substituted with exactly one hydroxy group.

In some embodiments, the imidazole comprising at least two electron withdrawing groups is represented by Formula (I) wherein:
R₁ is selected from the group consisting of H and substituted or unsubstituted C₁-C₆ alkyl;
R₂ is selected from the group consisting of substituted or unsubstituted C₁-C₆ alkyl, substituted C₆ aryl, and phenyl; and
R₃ and R₄ are each independently selected from the group consisting of substituted C₁-C₆ alkyl, wherein each independently selected substituted C₁-C₆ alkyl is substituted with one or more substituents selected from the group consisting of halogen, hydroxy, cyano, C₁-C₆ alkoxy, and carboxylic acid.

In some embodiments, the imidazole comprising at least two electron withdrawing groups is represented by:

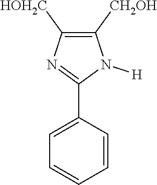 [SMILES: OCc1nc(-c2ccccc2)[nH]c1CO]

(2-phenyl-4,5-dihydroxymethylimidazole).

In some embodiments, the imidazole comprising at least two electron withdrawing groups is represented by:

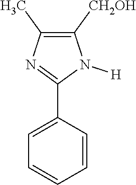

(4-methyl-2-phenyl-1H-imidazole-5-methanol, also referred to as 2-phenyl-4-methyl-5-hydroxymethylimidazole).

In some embodiments, compositions according to the disclosure comprise adducts of one or more imidazoles as described herein with one or more agents. In some embodiments, these imidazole adducts dissociate thermally to release one or more imidazoles.

In some embodiments, the one or more imidazoles with latent thermal activity are included in amounts ranging from about 0.5 wt. % to about 10 wt. %. In some embodiments, the one or more imidazoles with latent thermal activity are included in amounts ranging from about 1 wt. % to about 8 wt. %. In some embodiments, the one or more imidazoles with latent thermal activity are included in amounts ranging from about 2 wt. % to about 7 wt. %. In some embodiments, the one or more imidazoles with latent thermal activity are included in amounts ranging from about 2.5 wt. % to about 6.5 wt. %. In some embodiments, the one or more imidazoles with latent thermal activity are included in amounts ranging from about 3 wt. % to about 6 wt. %. In some embodiments, the one or more imidazoles with latent thermal activity are included in amounts ranging from about 2.5 wt. % to about 4.5 wt. %. In some embodiments, the one or more imidazoles with latent thermal activity are included in amounts ranging from about 1 wt. % to about 4 wt. %. In some embodiments, the one or more imidazoles with latent thermal activity are included in amounts ranging from about 2 wt. % to about 4 wt. %. In some embodiments, the one or more imidazoles with latent thermal activity are included in amounts ranging from about 2 wt. % to about 3.5 wt. %. In some embodiments, the one or more imidazoles with latent thermal activity are included in amounts ranging from about 2 wt. % to about 3 wt. %. In some embodiments, the one or more imidazoles with latent thermal activity are included in amounts ranging from about 2.5 wt. % to about 3.5 wt. %. In some embodiments, the one or more imidazoles with latent thermal activity referred to in this paragraph are one or more imidazoles comprising at least two electron withdrawing groups.

In some embodiments, the maleimide-containing resin, nadimide-containing resin, or itaconimide-containing resin is represented by, respectively:

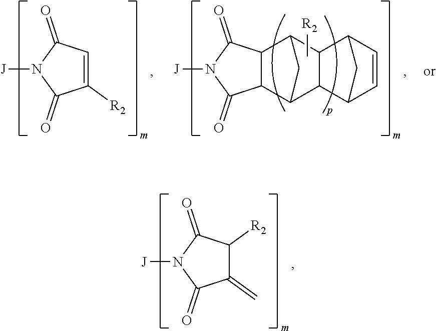

wherein:
m is 1-15,
p is 0-15,
each R₂ is independently selected from hydrogen or C₁-6 alkyl, and
J is a monovalent or a polyvalent radical comprising organic and/or organosiloxane radicals.

In some embodiments, J is a monovalent or polyvalent radical selected from:
hydrocarbyl or substituted hydrocarbyl species typically having in the range of about 6 up to about 500 carbon atoms, where the hydrocarbyl species is selected from alkyl, alkenyl, alkynyl, cycloalkyl, cycloalkenyl, aryl, alkylaryl, arylalkyl, aryalkenyl, alkenylaryl, arylalkynyl or alkynylaryl, provided, however, that X can be aryl only when X comprises a combination of two or more different species;
hydrocarbylene or substituted hydrocarbylene species typically having in the range of about 6 up to about 500 carbon atoms, where the hydrocarbylene species are selected from alkylene, alkenylene, alkynylene, cycloalkylene, cycloalkenylene, arylene, alkylarylene, arylalkylene, arylalkenylene, alkenylarylene, arylalkynylene or alkynylarylene,
substituted or unsubstituted C₆-C₁₀ aryl;
heterocyclic or substituted heterocyclic species typically having in the range of about 6 up to about 500 carbon atoms,
polysiloxane,
polysiloxane-polyurethane block copolymers, or
combinations of one or more of the above with a linker selected from a covalent bond, —O—, —S—, —NR—, —NR—C(O)—, —NR—C(O)—O—, —NR—C(O)—NR—, —S—C(O)—, —S—C(O)—O—, —S—C(O)—NR—, —O—S(O)₂—, —O—S(O)₂—O—, —O—S(O)₂—NR—, —O—S(O)—, —O—S(O)—O—, —O—S(O)—NR—, —O—NR—C(O)—, —O—NR—C(O)—O, —O—NR—C(O)—NR, —NR—O—C(O)—, —NR—O—C(O)—O—, —NR—O—C(O)—NR—, —O—NR—C(S)—, —O—NR—C(S)—O—, —O—NR—C(S)—NR—, —NR—O—C(S)—, —NR—O—C(S)—O—, —NR—O—C(S)—NR—, —O—C(S)—, —O—C(S)—O—, —O—C(S)—NR—, —NR—C(S)—, —NR—C(S)—O—, —NR—C(S)—NR—, —S—S(O)₂—, —S—S(O)₂—O—, —S—S(O)₂—NR—, —NR—O—S(O)—, —NR—O—S(O)—O—, —NR—O—S(O)—NR—, —NR—O—S(O)₂—, —NR—O—S(O)₂—O—, —NR—O—S(O)₂—NR—, —O—NR—S(O)—, —O—NR—S(O)—O—, —O—NR—S(O)—NR—, —O—NR—S(O)₂—O—, —O—NR—S(O)₂—NR—, —O—NR—S(O)₂—, —O—P(O)R₂—, —S—P(O)R₂—, or —NR—P(O)R₂—;
where each R is independently hydrogen, alkyl, or substituted alkyl.

In some embodiments, J is substituted or unsubstituted C₆ aryl, oxyalkyl, thioalkyl, aminoalkyl, carboxylalkyl, oxyalkenyl, thioalkenyl, aminoalkenyl, carboxyalkenyl, oxyalkynyl, thioalkynyl, aminoalkynyl, carboxyalkynyl, oxycycloalkyl, thiocycloalkyl, aminocycloalkyl, carboxycycloalkyl, oxycloalkenyl, thiocycloalkenyl, aminocycloalkenyl, carboxycycloalkenyl, heterocyclic, oxyheterocyclic, thioheterocyclic, aminoheterocyclic, carboxyheterocyclic, oxyaryl, thioaryl, aminoaryl, carboxyaryl, heteroaryl, oxyheteroaryl, thioheteroaryl, aminoheteroaryl, carboxyheteroaryl, oxyalkylaryl, thioalkylaryl, aminoalkylaryl, carboxyalkylaryl, oxyarylalkyl, thioarylalkyl, aminoarylalkyl, carboxyarylalkyl, oxyarylalkenyl, thioarylalkenyl, aminoarylalkenyl, carboxyarylalkenyl, oxyalkenylaryl, thioalkenylaryl, aminoalkenylaryl, carboxyalkenylaryl, oxyarylalkynyl, thioarylalkynyl, aminoarylalkynyl, carboxyarylalkynyl, oxyalkynylaryl, thioalkynylaryl, aminoalkynylaryl or carboxyalkynylaryl, oxyalkylene, thioalkylene, aminoalkylene, carboxyalkylene, oxyalkenylene, thioalkenylene, aminoalkenylene, carboxyalkenylene, oxyalkynylene, thioalkynylene, aminoalkynylene, carboxyalkynylene, oxycycloalkylene, thiocycloalkylene, aminocycloalkylene, carboxycycloalkylene, oxycycloalkenylene, thiocycloalkenylene, aminocycloalkenylene, carboxycycloalkenylene, oxyarylene, thioarylene, aminoarylene, carboxyarylene, oxyalkylarylene, thioalkylarylene, aminoalkylarylene, carboxyalkylarylene, oxyarylalkylene, thioarylalkylene, aminoarylalkylene, carboxyarylalkylene, oxyarylalkenylene, thioarylalkenylene, aminoarylalkenylene, carboxyarylalkenylene, oxyalkenylarylene, thioalkenylarylene, aminoalkenylarylene, carboxyalkenylarylene, oxyarylalkynylene, thioarylalkynylene, aminoarylalkynylene, carboxy arylalkynylene, oxyalkynylarylene, thioalkynylarylene, aminoalkynylarylene, carboxyalkynylarylene, heteroarylene, oxyheteroarylene, thioheteroarylene, aminoheteroarylene, carboxyheteroarylene, heteroatom-containing di- or polyvalent cyclic moiety, oxyheteroatom-containing di- or polyvalent cyclic moiety, thioheteroatom-containing di- or polyvalent cyclic moiety, aminoheteroatom-containing di- or polyvalent cyclic moiety, or a carboxyheteroatom-containing di- or polyvalent cyclic moiety.

In some embodiments, the maleimide-containing resin is represented by

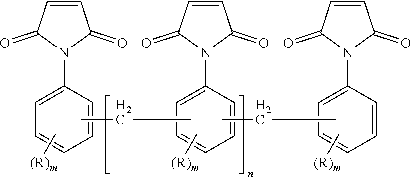

wherein:
each R is independently selected from the group consisting of H and substituted or unsubstituted alkyl;
each m is independently selected from the group consisting of 0, 1, 2, 3, and 4; and
n is 0, 1, 2, 3, 4, and 5.

In some embodiments, the composition comprises a compound represented by

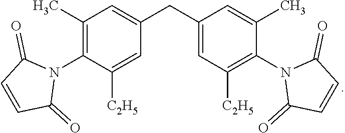 [SMILES: CCc1cc(Cc2cc(C)c(N3C(=O)C=CC3=O)c(CC)c2)cc(C)c1N1C(=O)C=CC1=O]

This compound is BMI-5100 (chemical name: 3,3′-dimethyl-5,5′-diethyl-4,4′-diphenylmethane bismaleimide; Daiwa Kasei, Japan), which is a compound that has an average number molecular weight of around 300 tested by gel permeation chromatography (GPC).

In some embodiments, the maleimide-containing resin is represented by

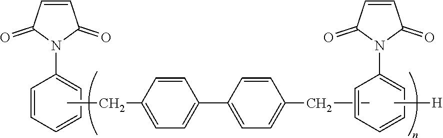

wherein n is 0, 1, 2, 3, 4, or 5.

In some embodiments, the maleimide-containing resin is a BMI resin with a maleimide equivalent weight from 180 to 400. A maleimide equivalent weight is the weight of resin in grams which contains one equivalent of maleimide functional group. In some embodiments, the maleimide-containing resin is a BMI resin with a maleimide equivalent weight of 220. In some embodiments, the maleimide-containing resin is a BMI resin with a maleimide equivalent weight of 300. In some embodiments, the maleimide-containing resin is a BMI resin with a maleimide equivalent weight of about 400. In some embodiments, the maleimide-containing resin is a BMI resin with a maleimide equivalent weight from about 390 to about 400. In some embodiments, the maleimide-containing resin is a BMI resin with a maleimide equivalent weight from 390 to 400.

In some embodiments, maleimide-containing resins are included in amounts ranging from about 1 wt. % to about 20 wt. %. In some embodiments, maleimide-containing resins are included in amounts ranging from about 1 wt. % to about 15 wt. %. In some embodiments, maleimide-containing resins are included in amounts ranging from about 3 wt. % to about 15 wt. %. In some embodiments, maleimide-containing resins are included in amounts ranging from about 1 wt. % to about 5 wt. %. In some embodiments, maleimide-containing resins are included in amounts ranging from about 5 wt. % to about 20 wt. %. In some embodiments, maleimide-containing resins are included in amounts ranging from about 5 wt. % to about 15 wt. %. In some embodiments, maleimide-containing resins are included in amounts ranging from about 10 wt. % to about 20 wt. %. In some embodiments, maleimide-containing resins are included in amounts ranging from about 10 wt. % to about 15 wt. %. In some embodiments, maleimide-containing resins are included in amounts ranging from about 12 wt. % to about 17 wt. %. In some embodiments, maleimide-containing resins are included in about 10 wt. %, about 11 wt. %, about 12 wt. %, about 13 wt. %, about 14 wt. %, about 15 wt. %, about 16 wt. %, about 17 wt. %, about 18 wt. %, about 19 wt. %, or about 20 wt. %.

In some embodiments, the itaconimide-containing resin is represented by:

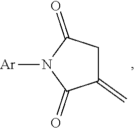

wherein Ar is a substituted or substituted aryl group.

In some embodiments, the itaconimide-containing resin is:

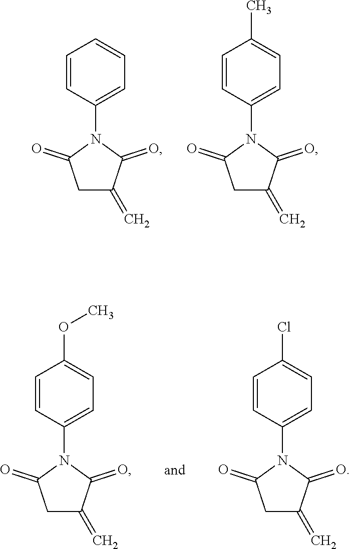

In some embodiments, the nadimide is represented by:

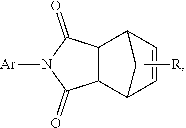

wherein:
Ar is substituted or unsubstituted aryl, and
R is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl.

Compositions of the disclosure, as noted above, include, among other constituents, one or more epoxy resins. A wide variety of epoxy-functionalized resins are contemplated for use herein, e.g., liquid-type epoxy resins based on bisphenol A, solid-type epoxy resins based on bisphenol A, liquid-type epoxy resins based on bisphenol F (e.g., Epiclon EXA-835LV), multifunctional epoxy resins based on phenol-novolac resin, dicyclopentadiene-type epoxy resins (e.g., Epiclon HP-7200L), naphthalene-type epoxy resins, and the like, as well as mixtures of any two or more thereof.

Exemplary epoxy-functionalized resins contemplated for use herein include the diepoxide of the cycloaliphatic alcohol, hydrogenated bisphenol A (commercially available as Epalloy 5000), a difunctional cycloaliphatic glycidyl ester of hexahydrophthallic anhydride (commercially available as Epalloy 5200), Epiclon EXA-835LV, Epiclon HP-7200L, and the like, as well as mixtures of any two or more thereof.

In certain embodiments, the epoxy component may include the combination of two or more different bisphenol based epoxies. These bisphenol based epoxies may be selected from bisphenol A, bisphenol F, or bisphenol S epoxies, or combinations thereof. In addition, two or more different bisphenol epoxies within the same type of resin (such A, F or S) may be used.

Commercially available examples of the bisphenol epoxies contemplated for use herein include bisphenol-F type epoxies (such as RE-404-S from Nippon Kayaku, Japan, and EPICLON 830 (RE1801), 830S (RE1815), 830A (REI 826) and 830W from Dai Nippon Ink & Chemicals, Inc., and RSL 1738 and YL-983U from Resolution) and bisphenol-A-type epoxies (such as YL-979 and 980 from Resolution).

The bisphenol epoxies available commercially from Dai Nippon and noted above are promoted as liquid undiluted epichlorohydrin-bisphenol F epoxies having much lower viscosities than conventional epoxies based on bisphenol A epoxies and have physical properties similar to liquid bisphenol A epoxies. Bisphenol F epoxy has lower viscosity than bisphenol A epoxies, all else being the same between the two types of epoxies, which affords a lower viscosity and thus a fast flow underfill sealant material. The EEW of these four bisphenol F epoxies is between 165 and 180. The viscosity at 25° C. is between 3,000 and 4,500 cps (except for RE1801 whose upper viscosity limit is 4,000 cps). The hydrolyzable chloride content is reported as 200 ppm for RE1815 and 830W, and that for RE1826 as 100 ppm.

The bisphenol epoxies available commercially from Resolution and noted above are promoted as low chloride containing liquid epoxies. The bisphenol A epoxies have a EEW (g/eq) of between 180 and 195 and a viscosity at 25° C. of between 100 and 250 cps. The total chloride content for YL-979 is reported as between 500 and 700 ppm, and that for YL-980 as between 100 and 300 ppm. The bisphenol F epoxies have a EEW (g/eq) of between 165 and 180 and a viscosity at 25° C. of between 30 and 60. The total chloride content for RSL-1738 is reported as between 500 and 700 ppm, and that for YL-983U as between 150 and 350 ppm.

In addition to the bisphenol epoxies, other epoxy compounds are contemplated for use as the epoxy component of the disclosed compositions. For instance, cycloaliphatic epoxies, such as 3,4-epoxycyclohexylmethyl-3,4-epoxycyclohexylcarbonate, can be used. Also monofunctional, difunctional or multifunctional reactive diluents may be used to adjust the viscosity and/or lower the Tg of the resulting resin material. Exemplary reactive diluents include butyl glycidyl ether, cresyl glycidyl ether, polyethylene glycol glycidyl ether, polypropylene glycol glycidyl ether, and the like.

Epoxies suitable for use herein include polyglycidyl derivatives of phenolic compounds, such as those available commercially under the tradename EPON, such as EPON 828, EPON 1001, EPON 1009, and EPON 1031 from Resolution; DER 331, DER 332, DER 334, and DER 542 from Dow Chemical Co.; and BREN-S from Nippon Kayaku. Other suitable epoxies include polyepoxides prepared from polyols and the like and polyglycidyl derivatives of phenol-formaldehyde novolacs, the latter of such as DEN 431, DEN 438, and DEN 439 from Dow Chemical. Cresol analogs are also available commercially under the tradename ARALDITE, such as ARALDITE ECN 1235, ARALDITE ECN 1273, and ARALDITE ECN 1299 from Ciba Specialty Chemicals Corporation. SU-8 is a bisphenol A-type epoxy novolac available from Resolution. Polyglycidyl adducts of amines, aminoalcohols and polycarboxylic acids are also useful in this invention, commercially available resins of which include GLYAMINE 135, GLYAMINE 125, and GLYAMINE 115 from F.I.C. Corporation; ARALDITE MY-720, ARALDITE 0500, and ARALDITE 0510 from Ciba Specialty Chemicals and PGA-X and PGA-C from the Sherwin-Williams Co.

Appropriate monofunctional epoxy coreactant diluents for optional use herein also include those that have a viscosity which is lower than that of the epoxy component, ordinarily, less than about 250 cps. The monofunctional epoxy coreactant diluents may have an epoxy group with an alkyl group of about 6 to about 28 carbon atoms, examples of which include C₆₋₂₈ alkyl glycidyl ethers, C₆₋₂₈ fatty acid glycidyl esters, C₆₋₂₈ alkylphenol glycidyl ethers, and the like.

In some embodiments, the epoxy resin is novolac epoxy EEW 200, novolac epoxy EEW 300, or novolac epoxy EEW 140.

In some embodiments, the epoxy resin is a compound represented by

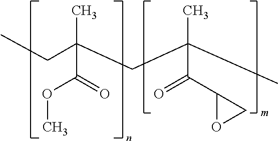

wherein n is 0, 1, 2, 3, 4, or 5, and m is 0, 1, 2, 3, 4, or 5.

In some embodiments, epoxy resins are included in amounts ranging from about 1 wt. % to about 30 wt. %. In some embodiments, epoxy resins are included in amounts ranging from about 1 wt. % to about 25 wt. %. In some embodiments, epoxy resins are included in amounts ranging from about 1 wt. % to about 20 wt. %. In some embodiments, epoxy resins are included in amounts ranging from about 1 wt. % to about 15 wt. %. In some embodiments, epoxy resins are included in amounts ranging from about 3 wt. % to about 15 wt. %. In some embodiments, epoxy resins are included in amounts ranging from about 1 wt. % to about 5 wt. %. In some embodiments, epoxy resins are included in amounts ranging from about 5 wt. % to about 20 wt. %. In some embodiments, epoxy resins are included in amounts ranging from about 5 wt. % to about 15 wt. %. In some embodiments, epoxy resins are included in amounts ranging from about 10 wt. % to about 20 wt. %. In some embodiments, epoxy resins are included in amounts ranging from about 15 wt. % to about 30 wt. %. In some embodiments, epoxy resins are included in amounts ranging from about 15 wt. % to about 25 wt. %. In some embodiments, epoxy resins are included in amounts ranging from about 10 wt. % to about 15 wt. %. In some embodiments, epoxy resins are included in about 10 wt. %, about 11 wt. %, about 12 wt. %, about 13 wt. %, about 14 wt. %, about 15 wt. %, about 16 wt. %, about 17 wt. %, about 18 wt. %, about 19 wt. %, about 20 wt. %, about 21 wt. %, about 22 wt. %, about 23 wt. %, about 24 wt. %, about 25 wt. %, about 26 wt. %, about 27 wt. %, about 28 wt. %, about 29 wt. %, about 30 wt. %.

In some embodiments, film forming binder resins are included in amounts ranging from about 1 wt. % to about 25 wt. %. In some embodiments, film forming binder resins are included in amounts ranging from about 1 wt. % to about 20 wt. %. In some embodiments, film forming binder resins are included in amounts ranging from about 10 wt. % to about 20 wt. %. In some embodiments, film forming binder resins are included in amounts ranging from about 13 wt. % to about 18 wt. %. In some embodiments, film forming binder resins are included in amounts ranging from about 14 wt. % to about 16 wt. %. In some embodiments, film forming binder resins are included in amounts of about 10 wt. %, about 11 wt. %, about 12 wt. %, about 13 wt. %, about 14 wt. %, about 15 wt. %, about 16 wt. %, about 17 wt. %, about 18 wt. %, about 19 wt. %, about 20 wt. %, about 21 wt. %, about 22 wt. %, about 23 wt. %, about 24 wt. %, or about 25 wt. %.

Compositions of the disclosure, as noted above, include among other constituents one or more (meth)acrylate-containing resins. In some embodiments, the (meth)acrylate resin is represented by

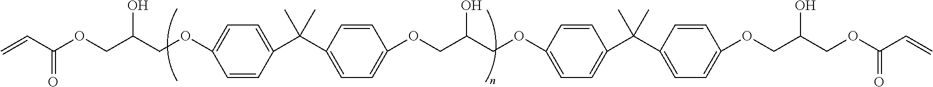

wherein n is 0, 1, 2, 3, 4, or 5.

In some embodiments, (meth)acrylate-containing resins are included in amounts ranging from about 1 wt. % to about 20 wt. %. In some embodiments, (meth)acrylate-containing resins are included in amounts ranging from about 1 wt. % to about 15 wt. %. In some embodiments, (meth)acrylate-containing resins are included in amounts ranging from about 3 wt. % to about 15 wt. %. In some embodiments, (meth)acrylate-containing resins are included in amounts ranging from about 1 wt. % to about 5 wt. %. In some embodiments, (meth)acrylate-containing resins are included in amounts ranging from about 5 wt. % to about 20 wt. %. In some embodiments, (meth)acrylate-containing resins are included in amounts ranging from about 5 wt. % to about 15 wt. %. In some embodiments, (meth)acrylate-containing resins are included in amounts ranging from about 10 wt. % to about 20 wt. %. In some embodiments, (meth)acrylate-containing resins are included in amounts ranging from about 10 wt. % to about 15 wt. %. In some embodiments, (meth)acrylate-containing resins are included in amounts ranging from about 12 wt. % to about 17 wt. %. In some embodiments, (meth)acrylate-containing resins are included in about 10 wt. %, about 11 wt. %, about 12 wt. %, about 13 wt. %, about 14 wt. %, about 15 wt. %, about 16 wt. %, about 17 wt. %, about 18 wt. %, about 19 wt. %, or about 20 wt. %.

Compositions of the disclosure, as noted above, include among other constituents one or more inorganic fillers. In some embodiments, the filler is an electrically non-conductive filler, such as silica. In some embodiments, the filler is (or comprises) silica, calcium silicate, aluminum hydroxide, magnesium hydroxide, calcium carbonate, magnesium carbonate, aluminum oxide (Al₂O₃), zinc oxide (ZnO), magnesium oxide (MgO), aluminum nitride (AlN), boron nitride (BN), carbon nanotubes, diamond, clay, aluminosilicate, and the like, as well as mixtures of any two or more thereof.

In some embodiments, the inorganic filler is an inorganic non-conductive filler comprising particles having a maximum particle size of 5 μm or less than 5 μm. For example, in some embodiments, the filler has a particle size in the from about 0.1 μm to about 5 μm or from 0.1 μm to 5 μm. In some embodiments, filler loadings are sufficient to meet underfill material requirements. In some embodiments, fillers are included in an amount ranging from about 10 wt. % to about 70 wt. %. In some embodiments, fillers are included in an amount ranging from about 20 wt. % to about 60 wt. %. In some embodiments, fillers are included in an amount ranging from about 25 wt. % to about 55 wt. %. In some embodiments, fillers are included in an amount ranging from about 30 wt. % to about 50 wt. %. In some embodiments, fillers are included in an amount ranging from about 35 wt. % to about 45 wt. %. In some embodiments, fillers are included in an amount ranging from about 35 wt. %, about 36 wt. %, about 37 wt. %, about 38 wt. %, about 39 wt. %, about 40 wt. %, about 41 wt. %, about 42 wt. %, about 43 wt. %, about 44 wt. %, or about 45 wt. %.

Compositions of the disclosure, as noted above, include among other constituents one or more additives selected from the group consisting of adhesion promoters and film formers.

As used herein, the term “adhesion promoters” refers to compounds that enhance the adhesive properties of the formulation to which they are introduced. Adhesion promoters can be organic or inorganic compounds and can include combinations thereof. Non-limiting examples of adhesion promoters include organo-zirconate compounds, organo-titanate compounds, and silane coupling agents. In some embodiments, the adhesion promoter is Z6040 from Dow.

In some embodiments, adhesion promoters are included in an amount ranging from about 0.1 wt. % to about 5 wt. %. In some embodiments, adhesion promoters are included in an amount ranging from about 0.1 wt. % to about 1.0 wt. %. In some embodiments, adhesion promoters are included in an amount ranging from about 0.5 wt. % to about 1.0 wt. %. In some embodiments, adhesion promoters are included in an amount ranging from about 0.5 wt. % to about 1.5 wt. %. In some embodiments adhesion promoters are included in an amount ranging from about 1 wt. % to about 2 wt. %, about 2 wt. % to about 3 wt. %, about 3 wt. % to about 4 wt. %, or about 4 wt. % to about 5 wt. %.

As used herein, the term “film formers” refers to compounds that assist in the formation of a film, such as (as a non-limiting example), by increasing the viscosity of the combined materials. Non-limiting examples of film formers including elastomeric additive components such as, but not limited to, copolymeric ethylene acrylic elastomers, natural or synthetic rubbers such as substituted polyethylenes, resins such as polyvinyl butyral resins and chlorosulfonated polyethylene synthetic rubbers (CSM), partially cross-linked butyl rubber compounds such as butyl rubber products commercially available from Royal Elastomers of New Jersey under the brand names KALAR®, DPR®, ISOLENE® and KALENE®, and ethylene acrylic elastomeric materials such as Vamac®, which is commercially available from the DuPont Corporation. Additional non-limiting examples of film formers include, but are not limited to, acrylic polymers such as copolymers of butyl acrylate-ethyl acrylate-acetonitrile and copolymers of ethyl acrylate-acetonitrile (e.g., polymers comprising glycidyl functional groups), such as copolymers available from Nagase JP.

In some embodiments, film formers are included in an amount ranging from about 15 to about 40 wt. %. In some embodiments, film formers are included in an amount ranging from about 15 to about 30 wt. %. In some embodiments, film formers are included in an amount ranging from about 20 to about 30 wt. %. In some embodiments, film formers are included in an amount ranging from about 22 to about 28 wt. %. In some embodiments, film formers are included in an amount ranging from about 23 to about 26 wt. %. In some embodiments, film formers are included in an amount ranging from about 23 to about 25 wt. %. In some embodiments, film formers are included in about 24 wt. %, about 25 wt. %, or about 26 wt. %.

In some embodiments, compositions of the disclosure further comprise one or more fluxing agents.

As used herein, the term “fluxing agents” refers to reducing agents which prevent oxides from forming on the surface of a molten metal. Non-limiting examples of fluxing agents include compounds having at least one (meth)acrylate group and at least one carboxylic acid group, carboxylic acids (including, but not limited to, compounds having one or more acrylic acid functional groups, rosin gum, dodecanedioic acid (commercially available as Corfree M2 from Aldrich), adipic acid, sebasic acid, polysebasic polynhydride, maleic acid, tartaric acid, citric acid, and the like), alcohols, hydroxyl acid and hydroxyl base, polyols (including, but not limited to, ethylene glycol, glycerol, 3-[bis(glycidyloxymethyl)methoxy]-1,2-propanediol, D-ribose, D-cellobiose, cellulose, 3-cyclohexene-1,1-dimethanol, and the like).

In some embodiments, fluxing agents are included in an amount ranging from about 1 to about 10 wt. %. In some embodiments, fluxing agents are included in an amount ranging from about 1 to about 5 wt. %. In some embodiments, fluxing agents are included in an amount ranging from about 5 to about 10 wt. %. In some embodiments, fluxing agents are included in an amount ranging from about 2 to about 8 wt. %. In some embodiments, fluxing agents are included in an amount ranging from about 3 to about 7 wt. %. In some embodiments, fluxing agents are included in an amount ranging from about 3 to about 5 wt. %. In some embodiments, fluxing agents are included in an amount ranging from about 3 to about 7 wt. %. In some embodiments, fluxing agents are included in an amount ranging from about 3 wt. %, about 4 wt. %, or about 5 wt. %.

Aspects of the disclosure also relate to methods of preparing B-stage films and/or cured films.

In some embodiments, the methods of preparing cured films comprise:
providing a composition comprising
   one or more resins selected from the group consisting of maleimide-containing resins, nadimide-containing resins, itaconimide-containing resins, epoxy resins, (meth)acrylate-containing resins, and phenolic-containing resins,
   one or more imidazoles with latent thermal activity,
   one or more inorganic fillers, and
   one or more additives selected from the group consisting of adhesion promoters and film formers;
casting the composition into a film; and
exposing the cast film to elevated temperature to cure the film.

In some embodiments, the methods of preparing cured films comprise:
providing a composition comprising
   one or more resins selected from the group consisting of maleimide-containing resins, nadimide-containing resins, itaconimide-containing resins, epoxy resins, (meth)acrylate-containing resins, and phenolic-containing resins,
   one or more imidazoles comprising at least two electron withdrawing groups,
   one or more inorganic fillers, and
   one or more additives selected from the group consisting of adhesion promoters and film formers;
casting the composition into a film; and
exposing the cast film to elevated temperature to cure the film.

In some embodiments, the methods of preparing cured films comprise:
providing a composition comprising
   one or more resins selected from the group consisting of maleimide-containing resins, nadimide-containing resins, itaconimide-containing resins, epoxy resins, (meth)acrylate-containing resins, and phenolic-containing resins,
   one or more imidazoles with latent thermal activity,
   one or more inorganic fillers,
   one or more additives selected from the group consisting of adhesion promoters and film formers, and
   one or more fluxing agents;
casting the composition into a film; and exposing the cast film to elevated temperature to cure the film.

In some embodiments, the methods of preparing cured films comprise:
providing a composition comprising
   one or more resins selected from the group consisting of maleimide-containing resins, nadimide-containing resins, itaconimide-containing resins, epoxy resins, (meth)acrylate-containing resins, and phenolic-containing resins,
   one or more imidazoles comprising at least two electron withdrawing groups,
   one or more inorganic fillers,
   one or more additives selected from the group consisting of adhesion promoters and film formers, and
   one or more fluxing agents;
casting the composition into a film; and
exposing the cast film to elevated temperature to cure the film.

In some embodiments of the methods of preparing cured films, the one or more resins selected from the group consisting of maleimide-containing resins, nadimide-containing resins, itaconimide-containing resins, epoxy resins, (meth)acrylate-containing resins, and phenolic-containing resins, wherein the maleimide-containing resins, nadimide-containing resins, itaconimide-containing resins, epoxy resins, (meth)acrylate-containing resins, and phenolic-containing resins are those disclosed elsewhere herein and, optionally, in the amounts disclosed elsewhere herein.

In some embodiments of the methods of preparing cured films, the one or more imidazoles are those disclosed elsewhere herein and, optionally, are present in the amounts disclosed elsewhere herein.

In some embodiments of the methods of preparing cured films, the one or more imidazoles are those disclosed elsewhere herein and, optionally, are present in the amounts disclosed elsewhere herein.

In some embodiments of the methods of preparing cured films, the one or more inorganic fillers are those disclosed elsewhere herein and, optionally, are present in the amounts disclosed elsewhere herein.

In some embodiments of the methods of preparing cured films, the one or more additives selected from the group consisting of adhesion promoters and film formers are those disclosed elsewhere herein and, optionally, are present in the amounts disclosed elsewhere herein.

In some embodiments of the methods of preparing cured films, the one or more fluxing agents are those disclosed elsewhere herein and, optionally, are present in the amounts disclosed elsewhere herein.

In some embodiments of the methods of preparing cured films, the one or more fluxing agents are compounds having at least one (meth)acrylate group and at least one carboxylic acid group and, optionally, are present in the amounts disclosed elsewhere herein.

In some embodiments of the methods of preparing cured films, the one or more fluxing agents are one or more fluxing agents described herein and, optionally, are present in the amounts disclosed elsewhere herein.

In some embodiments, films prepared according to methods of preparing cured films disclosed herein have the physical properties of films disclosed elsewhere herein. For example, in some embodiments, films prepared according to methods of preparing films disclosed herein have one or more of the Tg as measured by DMA, storage modulus at 25° C., storage modulus at 230° C., storage modulus at 250° C., CTE, DSC onset temperature as measured by DSC with a 10° C./min ramping rate, and minimum film melt viscosity measured using a DHR2 rheometer with a 10° C./min ramping rate in N₂ of cured films disclosed elsewhere herein.

In some embodiments, films prepared according to methods of preparing films disclosed herein have the following physical properties:
a Tg of >200° C. as measured by dynamic mechanical analysis (DMA),
a storage modulus at 25° C. of <6.5 GPa,
a storage modulus at 250° C.>0.1 GPa, and
a coefficient of thermal expansion (CTE)<250 ppm/ºC.

In some embodiments, films prepared according to methods of preparing films disclosed herein have the following physical properties:
a Tg of >230° C. as measured by dynamic mechanical analysis (DMA),
a storage modulus at 25° C. of <5 GPa,
a storage modulus at 230° C.>0.3 GPa, and
a coefficient of thermal expansion (CTE)<120 ppm/ºC.

In some embodiments, films prepared according to methods of preparing films disclosed herein have the following physical properties:
a Tg of >240° C. as measured by dynamic mechanical analysis (DMA),
a storage modulus at 25° C. of <5.5 GPa,
a storage modulus at 230° C.>0.6 GPa, and
a coefficient of thermal expansion (CTE)<80 ppm/ºC.

In some embodiments, films prepared according to methods of preparing films disclosed herein have the following physical properties:
a Tg of from 240° C. to 300° C. to as measured by dynamic mechanical analysis (DMA),
a storage modulus at 25° C. of from 4.0 GPa to 5.5 GPa, and
a storage modulus at 230° C. of from 0.6 GPa to 1.2 GPa.

In some embodiments, films prepared according to methods of preparing films disclosed herein have the following physical properties:
a Tg of from 240° C. to 300° C. to as measured by dynamic mechanical analysis (DMA),
a storage modulus at 25° C. of from 4.0 GPa to 5.5 GPa,
a storage modulus at 230° C. of from 0.6 GPa to 1.2 GPa, and
a minimum film melt viscosity from 900 Pa·s to 6,500 Pa·s as measured using a DHR2 rheometer with a 10° C./min ramping rate in N₂.

In some embodiments, films prepared according to methods of preparing films disclosed herein have the following physical properties:
a Tg of from 240° C. to 300° C. to as measured by dynamic mechanical analysis (DMA),
a storage modulus at 25° C. of from 4.0 GPa to 5.5 GPa,
a storage modulus at 230° C. of from 0.6 GPa to 1.2 GPa, and
a coefficient of thermal expansion (CTE) of from 50 ppm/° C. to 80 ppm/ºC.

In some embodiments, films prepared according to methods of preparing films disclosed herein have the following physical properties:
a Tg of from 240° C. to 300° C. to as measured by dynamic mechanical analysis (DMA),
a storage modulus at 25° C. of from 4.0 GPa to 5.5 GPa,
a storage modulus at 230° C. of from 0.6 GPa to 1.2 GPa,
a coefficient of thermal expansion (CTE) of from 50 ppm/° C. to 80 ppm/ºC, and
a minimum film melt viscosity from 900 Pa·s to 6,500 Pa's as measured using a DHR2 rheometer with a 10° C./min ramping rate in N₂.

### Examples

Exemplary embodiments of compositions according to the disclosure, including components thereof, are presented in Table 1. Imidazole A is 4-methyl-2-phenyl-1H-imidazole-5-methanol. Imidazole B is 2-phenyl-4,5-dihydroxymethylimidazole.

TABLE 1

| | | Inventive | Inventive | Inventive | Inventive |
|---|---|---|---|---|---|
| | Component (wt. %) | Example 1 | Example 2 | Example 3 | Example 4 |
| Resin | Film forming binder | 14.56 | 14.56 | 14.56 | 14.56 |
| | resin | | | | |
| Filler | Silica filler | 40 | 40 | 40 | 40 |
| Epoxy | Polymeric epoxy (EEW | 10 | 10 | 10 | 10 |
| | 310) | | | | |
| | Cresol novolac epoxy | 12.96 | | | 12.96 |
| | resin (EEW 200) | | | | |
| | Biphenyl aralkyl epoxy | | 12.96 | 12.96 | |
| | resin (EEW 276) | | | | |
| BMI resin | BMI resin (maleimide | 15.35 | | | |
| | equivalent weight 185) | | | | |
| | BMI resin (maleimide | | 15.35 | 15.35 | |
| | equivalent weight 221) | | | | |
| | BMI resin (maleimide | | | | 15.35 |
| | equivalent weight 393) | | | | |
| Additives | Fluxing agent | 3 | 3 | 3 | 3 |
| | Adhesion promoter | 1 | 1 | 1 | 1 |
| Curing Agent | Imidazole A | 3.14 | 3.14 | | 3.14 |
| | Imidazole B | | | 3.14 | |

| | | Inventive | Inventive | Inventive |
|---|---|---|---|---|
| | Component (wt. %) | Example 5 | Example 6 | Example 7 |
| Resin | Film forming binder | 14.56 | 14.56 | 14.56 |
| | resin | | | |
| Filler | Silica filler | 40 | 40 | 40 |
| Epoxy | Polymeric epoxy (EEW 310) | 10 | 10 | 10 |
| | Cresol novolac epoxy | 12.96 | 12.96 | |
| | resin (EEW 200) | | | |
| | Biphenyl aralkyl epoxy | | | 12.96 |
| | resin (EEW 276) | | | |
| BMI resin | BMI resin (maleimide | | | |
| | equivalent weight 185) | | | |
| | BMI resin (maleimide | | | |
| | equivalent weight 221) | | | |
| | BMI resin (maleimide | 15.35 | 15.35 | 15.35 |
| | equivalent weight 393) | | | |
| Additives | Fluxing agent | 4 | 3 | 3 |
| | Adhesion promoter | 1 | 1 | 1 |
| Curing Agent | Imidazole A | 2 | | 3.14 |
| | Imidazole B | | 3.14 | |

Properties of certain exemplary embodiments of compositions according to the disclosure are presented in Table 2.

TABLE 2

| | | Inventive | Inventive | Inventive | Inventive | Inventive |
|---|---|---|---|---|---|---|
| Physical Properties | | Example 1 | Example 2 | Example 3 | Example 4 | Example 5 |
| DSC | onset temperature | 148.19 | 151.61 | 173.74 | 147.86 | 150.26 |
| | (° C.) | | | | | |
| | peak temperature | 160.26 | 164.22 | 190.96 | 162.58 | 161.14 |
| | (° C.) | | | | | |
| Melt | lowest melt | 5,575 | 2,275 | 968 | 2,277 | 5,130 |
| viscosity | viscosity (Pa · s) | | | | | |
| DMA | Tg (° C.) | 245 | 291 | 262 | 290 | 296 |
| | Modulus at 25° C. | 4.910 | 5.085 | 4.138 | 4.964 | 4.112 |
| | (GPa) | | | | | |
| | Modulus at 230° C. | 1,200 | 970 | 764 | 939 | 688 |
| | (MPa) | | | | | |
| | Modulus at 250° C. | 1,096 | 694 | 546 | 698 | 596 |
| | (MPa) | | | | | |
| TMA | Tg (° C.) | 178 | 173 | 175 | 160 | 175 |
| | CTE1 (ppm/° C.) | 57 | 64 | 65 | 65 | 70 |
| | CTE2 (ppm/° C.) | 67 | 66 | 73 | 73 | 75 |

The components of an additional exemplary composition according to the disclosure (“Inventive Example 8”) and those of four comparative compositions (not within the scope of this disclosure) (Comparative Examples 1-4) are presented in Table 3A; physical properties of those compositions are presented in Table 3B. Imidazole A is 4-methyl-2-phenyl-1H-imidazole-5-methanol. Imidazole C is 2-phenylimidazole. Imidazole D is 2-ethyl-4-methyl-1H-imidazole-1-propanenitrile.

TABLE 3A

| | | Inventive | Comparative | Comparative | Comparative | Comparative |
|---|---|---|---|---|---|---|
| Component (wt. %) | | Example 8 | Example 1 | Example 2 | Example 3 | Example 4 |
| Resin | Film | 10.0 | 50.0 | 30.5 | 10.0 | 9.4 |
| | forming | | | | | |
| | binder resin | | | | | |
| Filler | Silica filler, | 40 | | 25 | 40 | |
| | 0.3 μm | | | | | |
| | Silica filler, | | | | | 40 |
| | 2 μm | | | | | |
| | Fumed | | 2 | | | |
| | silica filler | | | | | |
| Monomers | Epoxy | 27.52 | 30.13 | 24.20 | 14.56 | 18.4 |
| | BMI | 15.35 | | 7.2 | 15.23 | 15 |
| Additives | Fluxing | 4 | | | 3 | 3 |
| | agent | | | | | |
| | Z6040 | 1.13 | 1.03 | 0.8 | 1.13 | 1.13 |
| | adhesion | | | | | |
| | promoter | | | | | |
| Curing | Dicumyl | | | | 0.45 | |
| agent | peroxide | | | | | |
| | Imidazole | 2.00 (Imidazole | 0.01 (Imidazole | | | 3.00 (Imidazole |
| | | A) | C) | | | D) |
| | 4,4-DDS | | 4.00 | 5.10 | | |
| | Other | | 0.33 | 2.20 | | |
| | amines | | | | | |

TABLE 3B

| | | Inventive | Comparative | Comparative | Comparative | Comparative |
|---|---|---|---|---|---|---|
| Physical Property | | Example 8 | Example 1 | Example 2 | Example 3 | Example 4 |
| DSC | onset | 148.40 | 149.61 | 171.19 | 159.08 | 121.01 |
| | temperature | | | | | |
| | (° C.) | | | | | |
| | peak | 163.16 | 169.14 | 200.53 | 166.20 | 136.08 |
| | temperature | | | | | |
| | (° C.) | | | | | |
| | δT (° C.) | 15 | 20 | 30 | 7 | 15 |
| Melt | lowest melt | 5,936 | 60 | 843 | 1,727 | >10,000 |
| viscosity | viscosity | | | | | |
| | (Pa · s) | | | | | |
| | lowest melt | 143 | 149 | 134 | 138 | N/A |
| | viscosity | | | | | |
| | temperature | | | | | |
| | (° C.) | | | | | |
| DMA | Tg (° C.) | 277 | 152 | 272 | 155 | 231 |
| | Modulus at | 5.043 | 1.347 | 2.322 | 6.628 | 7.167 |
| | 25° C. (GPa) | | | | | |
| | Modulus at | 878 | 1.8 | 46 | 87 | 117 |
| | 230° C. | | | | | |
| | (MPa) | | | | | |
| | Modulus at | 640 | 2 | 32 | 95 | 103 |
| | 250° C. | | | | | |
| | (MPa) | | | | | |
| TMA | Tg (° C.) | 169 | 107 | 100 | 100 | 129 |
| | CTE1 | 67 | 120 | 88 | 67 | 53 |
| | (ppm/° C.) | | | | | |
| | CTE2 | 73 | 276 | 168 | 140 | 86 |
| | (ppm/° C.) | | | | | |

As shown in Table 3A, the composition of each of Inventive Example 8, Comparative Example 1, and Comparative Example 4 comprised an imidazole curing agent, but the composition of Comparative Example 1 and the composition of Comparative Example 4 did not comprise an imidazole with at least two electron withdrawing groups, whereas the composition of Inventive Example 8 did comprise an imidazole with at least two electron withdrawing groups. As shown in Table 3B, however, the composition of Inventive Example 8 had a ΔT from the DSC onset temperature to the DSC peak temperature that was less than 20° C., unlike the composition of Comparative Example 1 (rounded to the nearest integer).

As also shown in Table 3B, unlike the composition of Comparative Example 4, the composition of Inventive Example 8 had a DSC onset temperature of from 130° C. to 250° C. as measured by DSC with a 10° C./min ramping rate (specifically, of 148.40° C.) and a minimum film melt viscosity of from 10 Pa·s to 10,000 Pa·s as measured using a DHR2 rheometer with a 10° C./min ramping rate in N₂ (specifically, of 5,936 Pa·s).

The composition of Inventive Example 8 demonstrated good solder interconnect formation, no material entrapment, and no voids, and it also demonstrated a higher Tg, lower CTE, and better high temperature properties compared to the Comparative Examples. Although the composition of Comparative Example 3 also demonstrated good solder interconnect formation, no material entrapment, and no voids, the compositions of Comparative Examples 1-4 all demonstrated inferior high temperature properties compared Inventive Example 8. The compositions of Comparative Examples 1, 2, and 4 were deemed unsuitable for thermocompression bonding processes.

Thus, without wishing to be bound by theory, it is believed that a composition comprising an imidazole with latent thermal activity, such as an imidazole comprising at least two electron-withdrawing groups, provides features that include, but are not limited to, a DSC onset temperature, melt viscosity, and ΔT from the DSC onset temperature to the DSC peak temperature that make the composition more suitable for thermocompression bonding processes, whereas compositions comprising an imidazole without latent thermal activity, such as an imidazole with one or no electron-withdrawing groups, or compositions that lack an imidazole, are less suitable for thermocompression bonding processes.

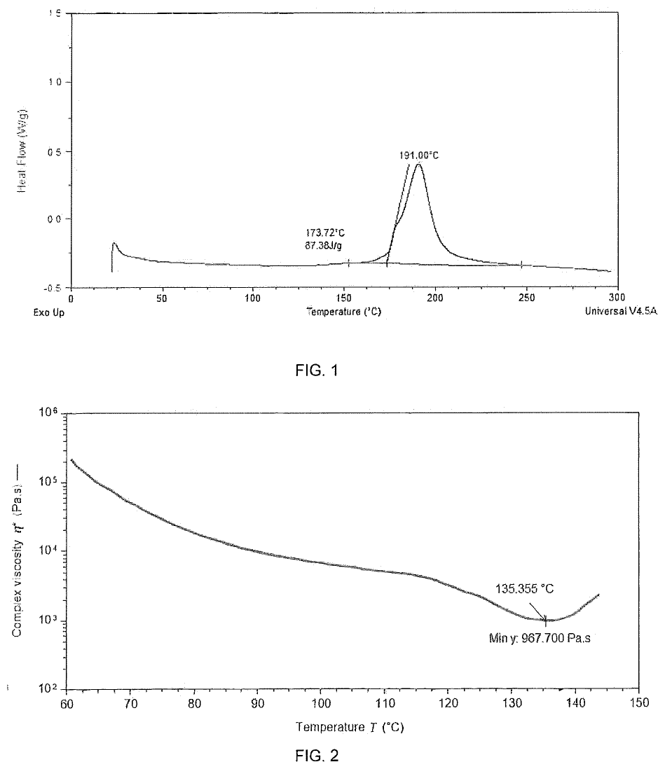

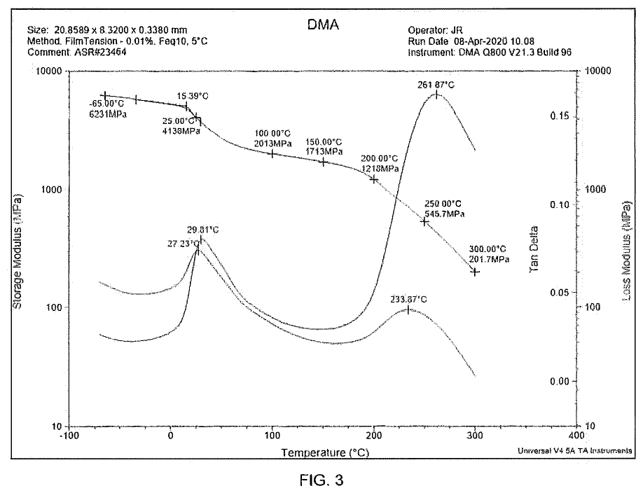

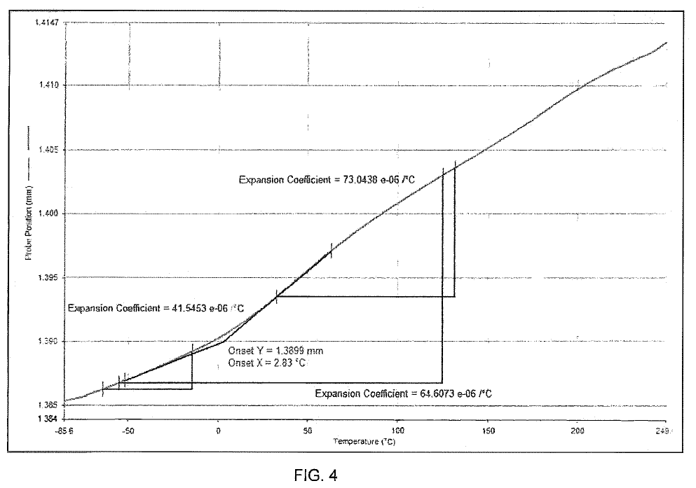

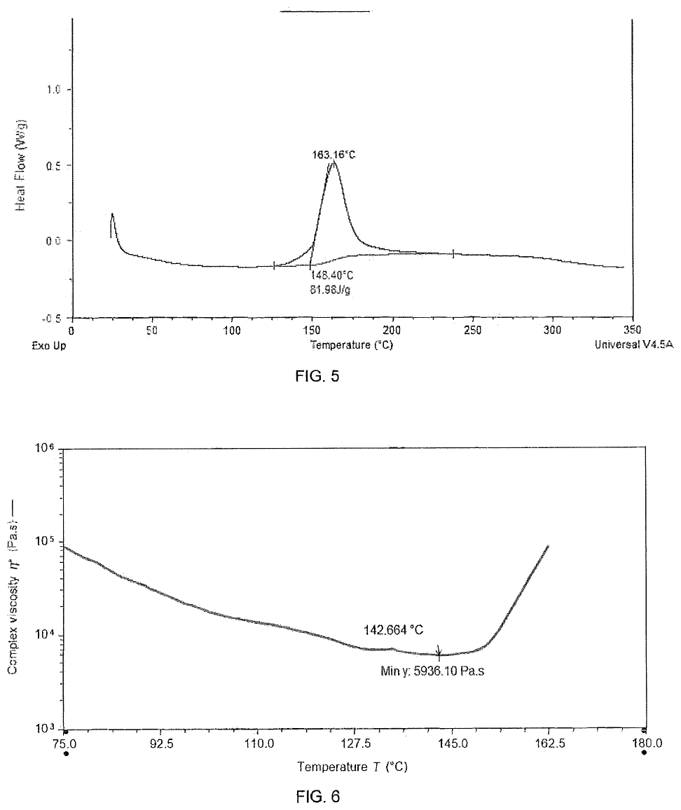

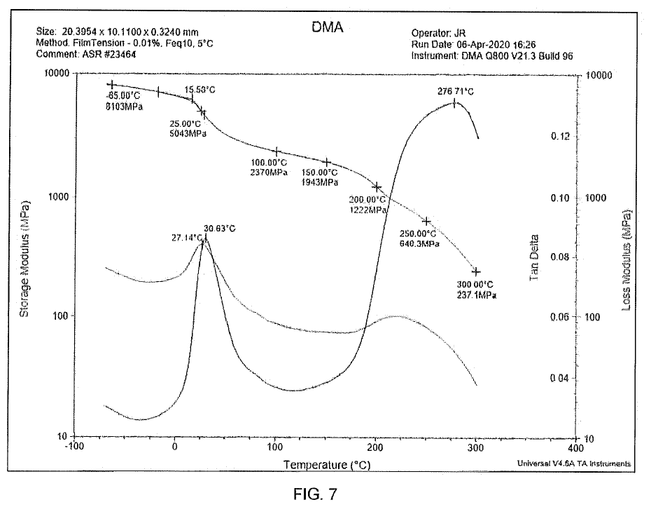

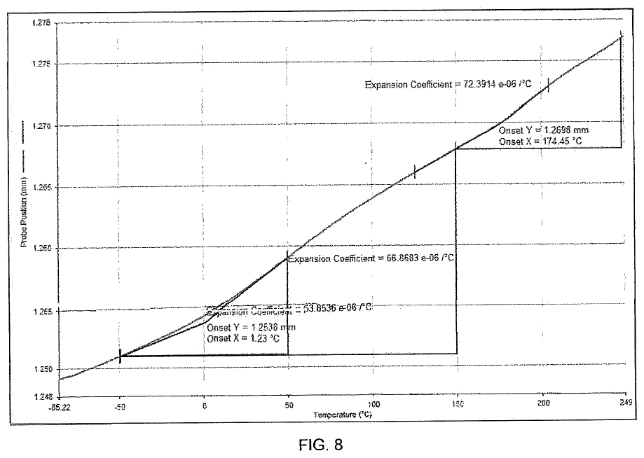

DSC, melt viscosity, DMA, and TMA data associated with exemplary composition Inventive Example 3 are provided in FIG. 1, FIG. 2, FIG. 3, and FIG. 4, respectively. DSC, melt viscosity, DMA, and TMA data associated with exemplary composition Inventive Example 8 are provided in FIG. 5, FIG. 6, FIG. 7, and FIG. 8, respectively.

What is claimed is:

1. A composition comprising:
one or more resins selected from the group consisting of maleimide-containing resins, nadimide-containing resins, itaconimide-containing resins, epoxy resins, (meth)acrylate-containing resins, and phenolic-containing resins,
one or more imidazoles with latent thermal activity,
one or more inorganic fillers, and
one or more additives selected from the group consisting of adhesion promoters and film formers,
wherein:
after the composition forms a film, the film has the following physical properties:
a Tg of >200° C. as measured by dynamic mechanical analysis (DMA),
a storage modulus at 25° C. of <6.5 GPa,
a storage modulus at 250° C.>0.1 GPa, and
a coefficient of thermal expansion (CTE)<250 ppm/ºC.

2. The composition of claim 1, wherein, after the composition forms a film, the film has the following physical properties:
a Tg of >230° C. as measured by dynamic mechanical analysis (DMA),
a storage modulus at 25° C. of <5 GPa,
a storage modulus at 230° C.>0.3 GPa, and
a coefficient of thermal expansion (CTE)<120 ppm/ºC.

3. The composition of claim 1, wherein the imidazole with latent activity is an imidazole comprising at least two electron withdrawing groups.

4. The composition of claim 1, wherein the imidazole is a substituted imidazole comprising an electron-withdrawing group on the 2-position and comprises a substituent on the 4-position, a substituent on the 5-position, and/or a substituent on the nitrogen at the 1-position.

5. The composition of claim 1, wherein the imidazole comprises at least two electron-withdrawing groups independently selected from organic groups that reduce electron density on the imidazole ring and/or attenuate the reactivity of the imidazole.

6. The composition of claim 1, wherein the imidazole comprises at least two electron-withdrawing groups independently selected from the group consisting of substituted or unsubstituted aryl groups, cyano (—CN), halide (—X), —CHO, —COOH, —NR₁R₂, wherein each of R₁ and R₂ is independently a hydrogen atom or a substituted or unsubstituted alkyl group, alkyl groups substituted with one or more groups independently selected from cyano (—CN), halide (—X)—CHO, —COOH, and —NR₁R₂, wherein each of R₁ and R₂ is independent selected from a hydrogen atom or a substituted or unsubstituted alkyl group, and oxygen-containing groups.

7. The composition of claim 1, wherein the imidazole comprises at least two electron-withdrawing groups independently selected from hydroxymethyl and phenyl.

8. The composition of claim 1, wherein the imidazole is represented by 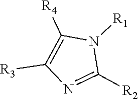
wherein:
R₁ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl,
R₂ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl,
R₃ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl, and
R₄ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl,
provided that the imidazole comprises at least two electron withdrawing groups.

9. The composition of claim 8, wherein R₂ is selected from the group consisting of C₁₋₆ alkyl and C₆ aryl.

10. The composition of claim 1, wherein the maleimide-containing resin is a compound represented by 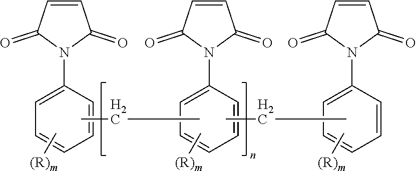
wherein:
each R is independently selected from the group consisting of H and substituted or unsubstituted alkyl;
each m is independently selected from the group consisting of 0, 1, 2, 3, or 4; and
n is 0, 1, 2, 3, 4, or 5, or is a compound represented by 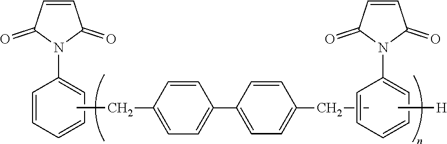
wherein n is 0, 1, 2, 3, 4, or 5.

11. The composition of claim 1, wherein the (meth)acrylate resin is represented by 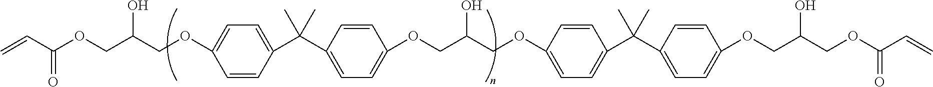
wherein n is 0, 1, 2, 3, 4, or 5.

12. The composition of claim 1, wherein the epoxy resin is a compound represented by 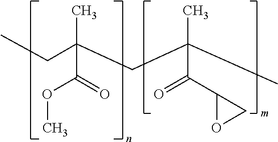
wherein n is 0, 1, 2, 3, 4, or 5, and m is 0, 1, 2, 3, 4, or 5.

13. The composition of claim 1, wherein, after the composition forms a film, the film has the following physical properties:
a differential scanning calorimetry (DSC) onset temperature from 130° C. to 250° C. as measured by DSC with a 10° C./min ramping rate, and
a minimum film melt viscosity from 10 Pa·s to 10,000 Pa·s as measured using a DHR2 rheometer with a 10° C./min ramping rate in N₂.

14. The composition of claim 1, wherein, after the composition forms a film, the film has the following physical properties:
a differential scanning calorimetry (DSC) onset temperature from 150° C. to 190° C. as measured by DSC with a 10° C./min ramping rate, and
a minimum film melt viscosity from 400 Pa·s to 7,000 Pa·s as measured using a DHR2 rheometer with a 10° C./min ramping rate in N₂.

15. The composition of claim 1, wherein, after the composition forms a film, the film has a ΔT from the DSC onset temperature to the DSC peak temperature that is less than 20° C. or less than 15° C.

16. The composition of claim 1, wherein, after the composition forms a film, the film has a ΔT from the DSC onset temperature to the DSC peak temperature that is less than 10° C. or less than 5° C.

17. A method of preparing a cured film, the method comprising
providing a composition according to claim 1;
casting the composition into a film; and
exposing the cast film to elevated temperature to cure the film.

18. A method of preparing a cured film, the method comprising
providing a composition comprising
one or more resins selected from the group consisting of maleimide-containing resins, nadimide-containing resins, itaconimide-containing resins, epoxy resins, (meth)acrylate-containing resins, and phenolic-containing resins,
one or more imidazoles with latent thermal activity,
one or more inorganic fillers, and
one or more additives selected from the group consisting of adhesion promoters and film formers;
casting the composition into a film; and
exposing the cast film to elevated temperature to cure the film.

19. The method according to claim 18, wherein the one or more imidazoles with latent thermal activity is one or more imidazoles comprising at least two electron withdrawing groups.

20. The method according to claim 18, wherein the one or more imidazoles is represented by 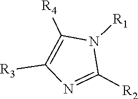
wherein:
R₁ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl,
R₂ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl,
R₃ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl, and
R₄ is selected from the group consisting of H, substituted or unsubstituted alkyl, substituted or unsubstituted alkenyl, substituted or unsubstituted alkynyl, substituted or unsubstituted aryl, and substituted or unsubstituted heteroaryl, provided that the imidazole comprises at least two electron withdrawing groups.

21. The method according to claim 18, wherein R₂ is selected from the group consisting of C₁-6 alkyl and C₆ aryl.

22. The method according to claim 18, wherein the maleimide-containing resin is a compound represented by 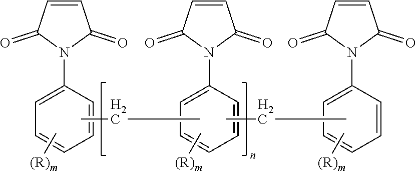
wherein:
each R is independent selected from the group consisting of H and substituted or unsubstituted alkyl;
each m is independent selected from the group consisting of 0, 1, 2, 3, or 4; and
n is 0, 1, 2, 3, 4, or 5, or is a compound represented by 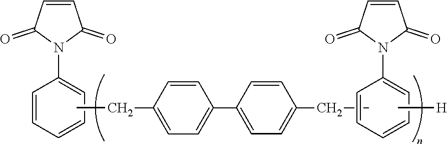
wherein n is 0, 1, 2, 3, 4, or 5.

23. The method according to claim 18, wherein the (meth)acrylate resin is represented by 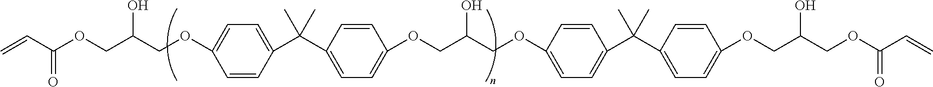
wherein n is 0, 1, 2, 3, 4, or 5.

24. The method according to claim 18, wherein the epoxy resin is a compound represented by 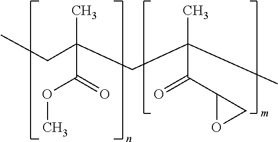
wherein n is 0, 1, 2, 3, 4, or 5, and m is 0, 1, 2, 3, 4, or 5.

25. A cured film prepared according to the method of claim 18.

26. A film prepared according to the method of claim 18, wherein the film has the following physical properties:
a Tg of >200° C. as measured by dynamic mechanical analysis (DMA),
a storage modulus at 25° C. of <6.5 GPa,
a storage modulus at 250° C.>0.1 GPa, and
a coefficient of thermal expansion (CTE)<250 ppm/° C.

27. A film prepared according to the method of claim 18, wherein the film has the following physical properties:
a Tg of >230° C. as measured by dynamic mechanical analysis (DMA),
a storage modulus at 25° C. of <5 GPa,
a storage modulus at 230° C.>0.3 GPa, and
a coefficient of thermal expansion (CTE)<120 ppm/° C.

28. The film of claim 25, wherein the film is an underfill film.

29. The film of claim 25, wherein the film is a wafer-level underfill film (WAUF).
